(19) United States
(12) Patent Application Publication
(10) Pub. No.: US 2024/0243059 A1
(43) Pub. Date: Jul. 18, 2024

(54) SEMICONDUCTOR DEVICE

(71) Applicant: SAMSUNG ELECTRONICS CO., LTD., SUWON-SI (KR)

(72) Inventors: SUNGHO JANG, Suwon-si (KR); JUNSOO KIM, Suwon-si (KR); ILGWEON KIM, Suwon-si (KR); DONGSOO WOO, Suwon-si (KR); MOONYOUNG JEONG, Suwon-si (KR); JOON HAN, Suwon-si (KR)

(21) Appl. No.: 18/372,881

(22) Filed: Sep. 26, 2023

(30) Foreign Application Priority Data
Jan. 12, 2023 (KR) 10-2023-0004752

(51) Int. Cl. H01L 23/528

(52) U.S. Cl. CPC H01L 23/528; H10B 12/482

(57) ABSTRACT

A semiconductor device may include a substrate including an insulating substrate. A semiconductor layer is on the substrate. An active pattern is on the semiconductor layer. A bit line is disposed in the insulating substrate. The bit line extends along a first direction parallel to a bottom surface of the substrate. A buried node contact penetrates the semiconductor layer in a direction perpendicular to the bottom surface of the substrate. A word line penetrates the active pattern in a second direction that is parallel to the bottom surface of the substrate and crosses the first direction. The active pattern may be connected to the bit line through the buried node contact. A top surface of the buried node contact may be higher than a bottom surface of the active pattern.

### CROSS-REFERENCE TO RELATED APPLICATIONS

This application claims priority under 35 U.S.C. § 119 to Korean Patent Application No. 10-2023-0004752, filed on Jan. 12, 2023 in the Korean Intellectual Property Office, the disclosure of which is incorporated by reference in its entirety herein.

### 1. TECHNICAL FIELD

The present disclosure relates to a semiconductor device, and in particular, to a semiconductor device including a substrate with an insulating substrate.

### 2. DISCUSSION OF RELATED ART

Semiconductor devices have become increasingly important in the electronics industry due to characteristics, such as being compact, multifunctional and cost efficient. Semiconductor devices include a semiconductor memory device for storing data, a semiconductor logic device for processing data, and a hybrid semiconductor device including both of memory and logic elements.

Due to the increased demand for electronic devices having a fast speed and/or low power consumption, the demand for semiconductor device to provide a fast operating speed and/or a low operating voltage has increased. Thus, there has been a demand to increase the integration density of the semiconductor device. Research is being conducted to provide a highly-integrated semiconductor device.

### SUMMARY

An embodiment of the present inventive concept provides a semiconductor device with an increased integration density.

An embodiment of the present inventive concept provides a semiconductor device with improved electrical and reliability characteristics.

According to an embodiment of the present inventive concept, a semiconductor device may include a substrate including an insulating substrate. A semiconductor layer is on the substrate. An active pattern is on the semiconductor layer. A bit line is disposed in the insulating substrate. The bit line extends along a first direction parallel to a bottom surface of the substrate. A buried node contact penetrates the semiconductor layer in a direction perpendicular to the bottom surface of the substrate. A word line penetrates the active pattern in a second direction that is parallel to the bottom surface of the substrate and crosses the first direction. The active pattern may be connected to the bit line through the buried node contact. A top surface of the buried node contact may be higher than a bottom surface of the active pattern.

According to an embodiment of the present inventive concept, a semiconductor device, includes a substrate including an insulating substrate. A first channel pattern and a second channel pattern is on the substrate. A bit line is disposed in the insulating substrate. The bit line extends along a first direction parallel to a bottom surface of the substrate. A first word line penetrates the first channel pattern in a second direction that is parallel to the bottom surface of the substrate and crosses the first direction. A second word line penetrates the second channel pattern in the second direction. A topmost surface of the bit line is located at a level lower than a bottom surface of the first word line and a bottom surface of the second word line.

According to an embodiment of the present inventive concept, a semiconductor device includes a substrate including a lower substrate, an upper substrate, and an insulating substrate disposed between the lower substrate and the upper substrate. A semiconductor layer is on the substrate. Active patterns are on the semiconductor layer. Each of the active patterns includes a first channel pattern and a second channel pattern. Bit lines are disposed in the insulating substrate. The bit lines extend along a first direction, and are spaced apart from each other in a second direction. Buried node contacts penetrate the semiconductor layer in a direction perpendicular to a bottom surface of the substrate. Word lines penetrate the active patterns in the second direction. The word lines are spaced apart from each other in the first direction. The first and second directions are parallel to the bottom surface of the substrate and cross each other. Each of the active patterns is connected to a corresponding one of the bit lines through a corresponding one of the buried node contacts. The first and second channel patterns of each of the active patterns are spaced apart from each other with the corresponding one of the buried node contacts interposed therebetween.

### BRIEF DESCRIPTION OF THE DRAWINGS

FIG. 1 is a plan view illustrating a semiconductor device according to an embodiment of the present inventive concept.

FIGS. 2A and 2B are cross-sectional views, which are respectively taken along lines A-A′ and B-B′ of FIG. 1 to illustrate a semiconductor device according to embodiments of the present inventive concept.

FIGS. 3A and 3B are cross-sectional views, which are respectively taken along the lines A-A′ and B-B′ of FIG. 1 to illustrate a semiconductor device according to embodiments of the present inventive concept.

FIGS. 4A and 4B are cross-sectional views, which are respectively taken along the lines A-A′ and B-B′ of FIG. 1 to illustrate a semiconductor device according to embodiments of the present inventive concept.

FIGS. 5A and 5B are cross-sectional views, which are respectively taken along the lines A-A′ and B-B′ of FIG. 1 to illustrate a semiconductor device according to embodiments of the present inventive concept.

FIGS. 6 and 7 are cross-sectional views, which are respectively taken along the line A-A′ of FIG. 1 to illustrate a semiconductor device according to embodiments of the present inventive concept.

FIG. 8 is a cross-sectional view, which is respectively taken along the line A-A′ of FIG. 1 to illustrate a semiconductor device according to an embodiment of the present inventive concept.

FIGS. 9 to 20B are diagrams illustrating a method of fabricating a semiconductor device, according to embodiments of the present inventive concept.

FIGS. 21A and 21B are cross-sectional views, which are respectively taken along lines A-A′ and B-B′ of FIG. 13 to illustrate a method of fabricating a semiconductor device, according to embodiments of the present inventive concept.

FIGS. 22A and 22B are cross-sectional views, which are respectively taken along lines A-A′ and B-B′ of FIG. 15 to illustrate a method of fabricating a semiconductor device, according to embodiments of the present inventive concept.

FIGS. 23A and 23B are cross-sectional views, which are respectively taken along lines A-A′ and B-B′ of FIG. 17 to illustrate a method of fabricating a semiconductor device, according to embodiments of the present inventive concept.

FIGS. 24 and 25 are cross-sectional views illustrating a method of fabricating a semiconductor device, according to embodiments of the present inventive concept.

FIG. 26 is a cross-sectional view illustrating a method of fabricating a semiconductor device according to an embodiment of the present inventive concept.

### DETAILED DESCRIPTION OF EMBODIMENTS

Embodiments of the present inventive concept will now be described more fully with reference to the accompanying drawings, in which non-limiting embodiments are shown.

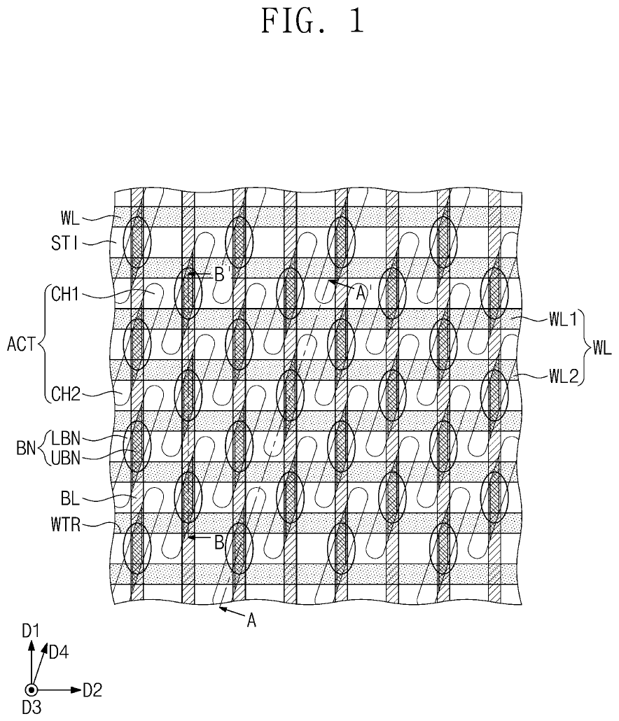

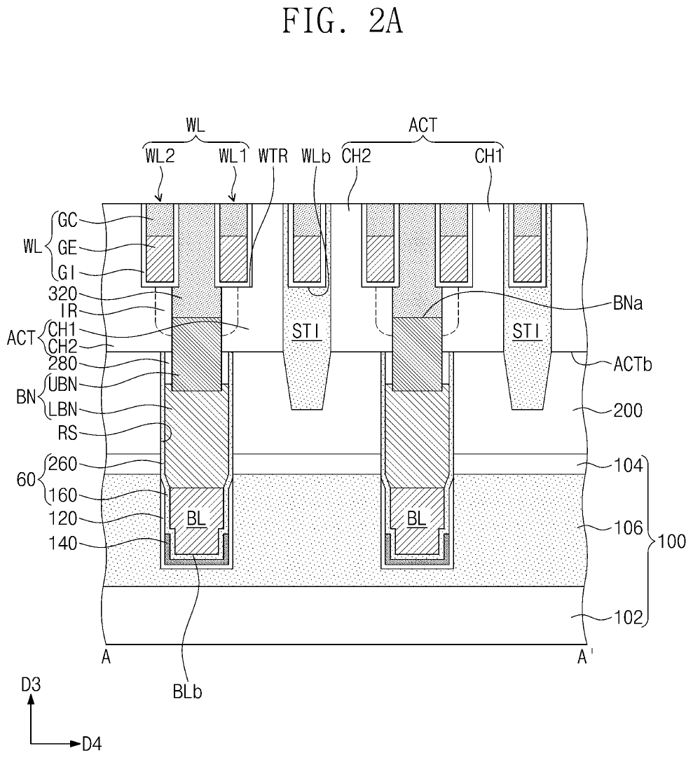

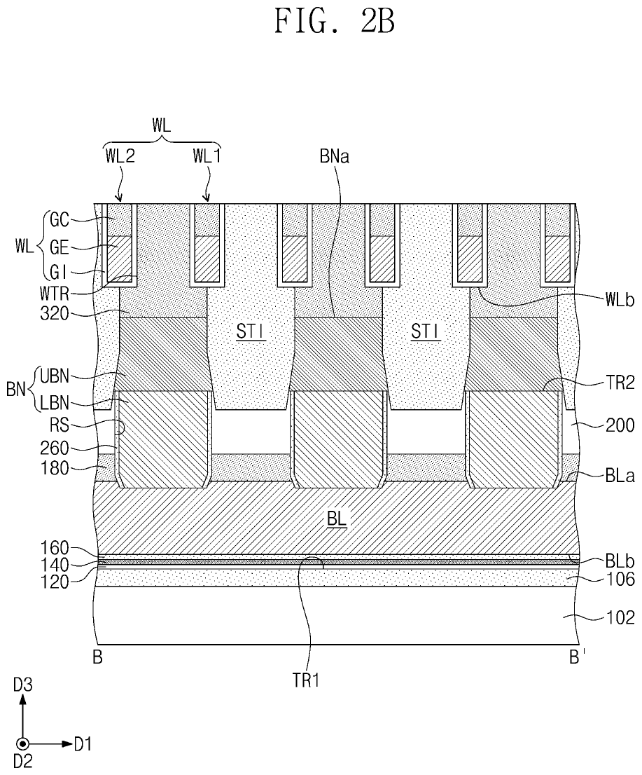

FIG. 1 is a plan view illustrating a semiconductor device according to an embodiment of the present inventive concept. FIGS. 2A and 2B are cross-sectional views, which are respectively taken along lines A-A′ and B-B′ of FIG. 1 to illustrate a semiconductor device according to an embodiment of the present inventive concept.

Referring to FIGS. 1, 2A, and 2B, a substrate 100 may be provided. The substrate 100 may be extended along a first direction D1 and a second direction D2. The first direction D1 and the second direction D2 may be parallel to a bottom surface of the substrate 100 and may cross each other.

In an embodiment, the substrate 100 may be a silicon-on-insulator (SOI) substrate. For example, the substrate 100 may include a lower substrate 102, an upper substrate 104, and an insulating substrate 106 therebetween. The lower substrate 102, the insulating substrate 106, and the upper substrate 104 may be sequentially stacked in a third direction D3. The third direction D3 may be perpendicular to the bottom surface of the substrate 100 and may be a vertical direction. In an embodiment, each of the lower and upper substrates 102 and 104 may be independently formed of or include a semiconductor material. The insulating substrate 106 may be formed of or include an insulating material. For example, the insulating substrate 106 may be formed of or include silicon oxide. However, embodiments of the present inventive concept are not necessarily limited thereto.

A semiconductor layer 200 may be provided on the substrate 100. For example, the semiconductor layer 200 may cover a top surface of the substrate 100. The semiconductor layer 200 may be formed of or include a semiconductor material. In an embodiment, the semiconductor layer 200 may be formed of or include at least one of silicon, silicon germanium, or oxide semiconductor materials. For example, the oxide semiconductor materials may include at least one compound selected from InₓGa_{y}Zn_{z}O, InₓGa_{y}Si_{z}O, InₓSn_{y}Zn_{z}O, In Zn, O, ZnxO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O. However, embodiments of the present inventive concept are not necessarily limited thereto. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements. In an embodiment, the semiconductor layer 200 may be formed of or include indium gallium zinc oxide (IGZO). The semiconductor layer 200 may be a single layer, which is made of a single material, or a composite layer, which is made of two or more materials. As an example, the semiconductor layer 200 may be an epitaxial pattern, which is formed by a selective epitaxial growth (SEG) process.

An active pattern ACT may be provided on the semiconductor layer 200. In an embodiment, a plurality of active patterns ACT may be provided. The active patterns ACT may be spaced apart from each other in the first direction D1 and the second direction D2. In an embodiment, each of the active patterns ACT may be a bar-shaped pattern elongated in a fourth direction D4. The fourth direction D4 may be parallel to the bottom surface of the substrate 100 and may intersect the first and second directions D1 and D2.

The active pattern ACT may be formed of or include a semiconductor material. As an example, the active pattern ACT may be formed of or include at least one material selected from silicon, silicon germanium, and oxide semiconductor materials. Alternatively, the active pattern ACT may be formed of or include IGZO. The active pattern ACT may be a single layer, which is made of a single material, or a composite layer, which is made of two or more materials. As an example, in an embodiment the active pattern ACT may be an epitaxial pattern, which is formed by a selective epitaxial growth (SEG) process.

Each of the active patterns ACT may include a first channel pattern CH1 and a second channel pattern CH2, which are spaced apart from each other in the fourth direction D4. The first and second channel patterns CH1 and CH2 may be spaced apart from each other with a buried node contact BN disposed therebetween (e.g., in the fourth direction D4) which will be described below. The first and second channel patterns CH1 and CH2 may be connected to the buried node contacts BN, respectively. In the present specification, the expression “A is connected to B” may be used to not only represent that “A is in direct contact with B” but also represent that “A is electrically connected to B.” even if they are not in physical contact with each other.

A device isolation pattern STI may be provided to enclose each of the active patterns ACT. As an example, the device isolation pattern STI may be provided to enclose a side surface (e.g., a lateral side surface) of each of the active patterns ACT. The device isolation pattern STI may separate the active patterns ACT from each other. The device isolation pattern STI between the active patterns ACT may extend into the semiconductor layer 200. As an example, the device isolation pattern STI between the active patterns ACT may extend into the semiconductor layer 200 in the third direction D3. A bottom surface of the device isolation pattern STI may be located at a level that is lower than a bottom surface ACTb of the active pattern ACT and is higher than the top surface of the substrate 100, such as a topmost surface of the upper substrate 104.

The device isolation pattern STI may be formed of or include an insulating material. As an example, in an embodiment the device isolation pattern STI may be formed of or include at least one compound selected from silicon oxide and silicon nitride. The device isolation pattern STI may be a single layer, which is made of a single material, or a composite layer, which is made of two or more materials.

A bit line BL may be disposed in the substrate 100. In an embodiment, the bit line BL may be provided in the insulating substrate 106 and may extend along the first direction D1. In an embodiment, a plurality of bit lines BL may be provided. The bit lines BL may be spaced apart from each other in the second direction D2. The bit line BL may be enclosed by the insulating substrate 106. As an example, side surfaces (e.g., lateral side surfaces) and a bottom surface BLb of the bit line BL may be covered with the insulating substrate 106. A top surface (e.g., a topmost surface BLa) of the bit line BL may be located at a level lower than the topmost surface of the substrate 100 (e.g., the topmost surface of the upper substrate 104). The bottom surface BLb of the bit line BL may be located at a level higher than a bottom surface of the insulating substrate 106. When measured at different levels, widths of the bit line BL in the fourth direction D4 may be equal to, or different from, each other. As an example, the width of the bit line BL in the fourth direction D4 may be larger at its upper portion than at its lower portion. However, embodiments of the present inventive concept are not necessarily limited thereto.

The bit line BL may be formed of a single material or two or more materials. The bit line BL may include a conductive material. As an example, in an embodiment the bit line BL may be formed of or include at least one material selected from doped polysilicon, metallic materials (e.g., Ti, Mo, W, Cu, Co, Al, Ta, Ru, Ir, and so forth), metal nitride materials of the metallic materials, and metal silicide materials of the metallic materials.

The buried node contact BN may be arranged to penetrate the semiconductor layer 200. As an example, the buried node contact BN may penetrate the semiconductor layer 200 in the third direction D3. In an embodiment, a plurality of buried node contacts BN may be provided. In an embodiment, the buried node contacts BN may be spaced apart from each other in the first and second directions D1 and D2. As an example, the buried node contacts BN, which are adjacent to each other in the second direction D2, may be spaced apart from each other by the device isolation pattern STI.

The buried node contact BN may extend into the substrate 100. In the substrate 100, the buried node contact BN may be connected to the bit line BL (e.g., directly connected thereto in the third direction D3). The buried node contact BN may also extend into a region between the first and second channel patterns CH1 and CH2 of the active pattern ACT. The first and second channel patterns CH1 and CH2 of the active pattern ACT may be spaced apart from each other in the fourth direction D4 by the buried node contact BN interposed therebetween. The buried node contact BN may be connected to (e.g., directly connected thereto) the active pattern ACT. As an example, the buried node contact BN may be connected to each of the first and second channel patterns CH1 and CH2 of the active pattern ACT. Each of the active patterns ACT may be connected (e.g., electrically connected and indirectly physically connected) to a corresponding one of the bit lines BL through a corresponding one of the buried node contacts BN.

In an embodiment, the buried node contact BN may include a lower buried node contact LBN and an upper buried node contact UBN. The lower buried node contact LBN may be connected to (e.g., directly connected thereto) the bit line BL, and the upper buried node contact UBN may be connected to (e.g., indirectly connected thereto) the bit line BL by the lower buried node contact LBN. The upper buried node contact UBN may be connected to (e.g., directly connected thereto) each of the first and second channel patterns CH1 and CH2 of the active pattern ACT, and the lower buried node contact LBN may be connected to (e.g., indirectly connected thereto) each of the first and second channel patterns CH1 and CH2 of the active pattern ACT through the upper buried node contact UBN.

A top surface of the lower buried node contact LBN may be located at a level that is lower than the bottom surface ACTb of the active pattern ACT and is higher than the top surface of the substrate 100, such as a topmost surface of the upper substrate 104. As an example, the top surface of the lower buried node contact LBN may be located at a level higher than the bottom surface of the device isolation pattern STI. The lower buried node contact LBN may be spaced apart from the active pattern ACT. A bottom surface of the lower buried node contact LBN may be located at a level lower than the top surface of the substrate 100. For example, in an embodiment, the bottom surface of the lower buried node contact LBN may be disposed at a level between a top surface of the insulating substrate 106 and a lower surface of the insulating substrate 106. However, embodiments of the present inventive concept are not necessarily limited thereto.

A bottom surface of the upper buried node contact UBN may be located at a level that is lower than the bottom surface ACTb of the active pattern ACT and is higher than the top surface of the substrate 100. As an example, the bottom surface of the upper buried node contact UBN may be located at a level higher than the bottom surface of the device isolation pattern STI. A top surface of the upper buried node contact UBN (e.g., a top surface BNa of the buried node contact BN) may be located at a level higher than the bottom surface ACTb of the active pattern ACT. As an example, a side surface (e.g., a lateral side surface) of the upper buried node contact UBN may be in direct contact with a side surface (e.g., a lateral side surface) of the first channel pattern CH1 and a side surface (e.g., a lateral side surface) of the second channel pattern CH2. However, embodiments of the present inventive concept are not necessarily limited thereto.

Widths of the buried node contact BN measured at different levels may be equal to, or different from, each other. In an embodiment, when measured in the fourth direction D4, a width of the lower buried node contact LBN may be larger than a width of the upper buried node contact UBN. However, embodiments of the present inventive concept are not necessarily limited thereto. In an embodiment, when measured in the fourth direction D4, the width of the lower buried node contact LBN may be larger than the width of the bit line BL. In an embodiment, the buried node contact BN may be formed of or include at least one material selected from doped polysilicon, metallic materials (e.g., Ti, Mo, W, Cu, Co, Al, Ta, Ru, Ir, and so forth), metal nitride materials of the metallic materials, and metal silicide materials of the metallic materials. As an example, each of the upper and lower buried node contacts UBN and LBN may be formed of or include polysilicon doped with impurities. As another example, the upper buried node contact UBN may be formed of or include a metallic material, while the lower buried node contact LBN may be formed of or include doped polysilicon. However, embodiments of the present inventive concept are not necessarily limited thereto.

A word line WL may extend along the second direction D2 to cross the active patterns ACT. As an example, the word line WL may be provided to cross the active patterns ACT and the device isolation pattern STI in the second direction D2. In an embodiment, a plurality of word lines WL may be provided. The word lines WL may be spaced apart from each other in the first direction D1. In an embodiment, a bottom surface WLb of the word line WL may be located at a level higher than the topmost surface BLa of the bit line BL. As an example, the bottom surface WLb of the word line WL may be located at a level higher than the bottom surface ACTb of the active pattern ACT.

As an example, in an embodiment the word lines WL may include a first word line WL1 and a second word line WL2, which are adjacent to each other in the first direction D1. A pair of the first and second word lines WL1 and WL2 may be provided on each of the active patterns ACT to cross the active pattern ACT thereunder. As an example, the first word line WL1 may be disposed to cross the first channel pattern CH1 of the active pattern ACT, and the second word line WL2 may be disposed to cross the second channel pattern CH2 of the active pattern ACT.

In an embodiment, each of the word lines WL may include a gate electrode GE, a gate insulating pattern GI, and a gate capping pattern GC. The gate electrode GE may be provided to cross the active patterns ACT and the device isolation pattern STI in the second direction D2. The gate insulating pattern GI may be interposed between the gate electrode GE and the active patterns ACT. The gate capping pattern GC may cover a top surface of the gate electrode GE. In an embodiment, the gate electrode GE may be formed of or include at least one of conductive materials. In an embodiment, the gate insulating pattern GI may be formed of or include at least one of silicon oxide or high-k dielectric materials. The gate capping pattern GC may be formed of or include silicon nitride. However, embodiments of the present inventive concept are not necessarily limited thereto.

Each of the first and second channel patterns CH1 and CH2 may include a channel region, which is provided adjacent to the word line WL. Each of the first and second channel patterns CH1 and CH2 may further include a first source/drain region, which is provided adjacent to the buried node contact BN (e.g., in an impurity region IR to be described below). Each of the first and second channel patterns CH1 and CH2 may further include a second source/drain region, which is provided adjacent to a data storage pattern. Each bit line BL may be connected to the first source/drain region of each of the first and second channel patterns CH1 and CH2. For example, the semiconductor device according to an embodiment of the present inventive concept may be configured such that two transistors share one of the bit lines BL. In an embodiment, when the semiconductor device is operated, a body bias may be applied to the semiconductor layer 200.

A bit line capping pattern 180 may be provided on the bit line BL. As an example, the bit line capping pattern 180 may be provided on (e.g., disposed directly thereon in the third direction D3) a top surface of the bit line BL. A top surface of the bit line capping pattern 180 may be located at a level that is less than or equal to a bottom surface of the semiconductor layer 200. In an embodiment, a plurality of bit line capping patterns 180 may be provided. The bit line capping patterns 180, which are adjacent to each other in the first direction D1, may be spaced apart from each other by the buried node contact BN. In an embodiment, the bit line capping pattern 180 may be formed of or include at least one of silicon oxide or silicon nitride. However, embodiments of the present inventive concept are not necessarily limited thereto. The bit line capping pattern 180 may be formed of a single material or two or more materials.

A lower node capping pattern 280 may be provided on (e.g., disposed directly thereon in the third direction D3) the lower buried node contact LBN. As an example, the lower node capping pattern 280 may be provided on (e.g., disposed directly thereon) the top surface of the lower buried node contact LBN. In an embodiment, a top surface of the lower node capping pattern 280 may be located at a level, which is less than or equal to the bottom surface ACTb of the active pattern ACT. The lower node capping pattern 280 may cover the side surface (e.g., lateral side surface) of a portion of the upper buried node contact UBN. As an example, the lower node capping pattern 280 may cover a side surface (e.g., a lateral side surface) of a lower portion of the upper buried node contact UBN. The lower node capping pattern 280 may be interposed between the side surface (e.g., a portion of the lateral side surface) of the upper buried node contact UBN and the semiconductor layer 200. In an embodiment, the lower node capping pattern 280 may be formed of or include silicon nitride. However, embodiments of the present inventive concept are not necessarily limited thereto.

An upper node capping pattern 320 may be provided on (e.g., disposed directly thereon) the upper buried node contact UBN. For example, the upper node capping pattern 320 may be provided on a top surface of the upper buried node contact UBN (e.g., disposed directly on the top surface BNa of the buried node contact BN in the third direction D3). The upper node capping pattern 320 may be interposed between the first and second channel patterns CH1 and CH2 of the active pattern ACT. As an example, the upper node capping pattern 320 may be extended along the third direction D3, between the first and second channel patterns CH1 and CH2 of the active pattern ACT. In an embodiment, the upper node capping pattern 320 may be formed of or include silicon oxide. However, embodiments of the present inventive concept are not necessarily limited thereto.

An impurity region IR may be provided in the active pattern ACT. The impurity region IR may be provided in each of the first and second channel patterns CH1 and CH2 of the active pattern ACT. The impurity region IR may be formed in a region adjacent to the upper node capping pattern 320 and the buried node contact BN, such as adjacent to lateral side surfaces of the upper node capping pattern 320 and the upper buried node contact UBN. The impurity region IR may be doped with impurities (e.g., n-type or p-type impurities). In an embodiment, the upper buried node contact UBN may be formed of or include doped polysilicon, and an impurity concentration of the impurity region IR may be lower than that of the upper buried node contact UBN. However, embodiments of the present inventive concept are not necessarily limited thereto.

A shielding pattern 140 may be interposed between the bit line BL and the insulating substrate 106. The shielding pattern 140 may enclose at least a portion of the bit line BL. For example, the shielding pattern 140 may cover a side surface (e.g., a lateral side surface) of a lower portion of the bit line BL and the bottom surface BLb of the bit line BL. The shielding pattern 140 may extend along the bit line BL and in the first direction D1. In an embodiment, the topmost surface of the shielding pattern 140 may be located at a level that is higher than the bottom surface BLb of the bit line BL.

The shielding pattern 140 may include a conductive material. As an example, in an embodiment the shielding pattern 140 may be formed of or include at least one material selected from a doped polysilicon, metallic materials (e.g., Ti, Mo, W, Cu, Co, Al, Ta, Ru, Ir, and so forth), metal nitride materials of the metallic materials, and metal silicide materials of the metallic materials. The shielding pattern 140 may suppress a coupling phenomenon between the bit lines BL.

An insulating liner 60 may be provided on a side surface of the buried node contact BN (e.g., disposed directly on a lateral side surface of the buried node contact BN), the side surface of the bit line BL (e.g., disposed directly on a lateral side surface of the bit line BL), and the bottom surface BLb of the bit line BL (e.g., disposed directly on a bottom surface BLb of the bit line BL). The insulating liner 60 may enclose the side surface (e.g., lateral side surfaces) of the buried node contact BN, and the side surface of the bit line BL, and the bottom surface BLb of the bit line BL. In an embodiment, the insulating liner 60 may include a lower insulating liner 160, which is provided to enclose the side surface and the bottom surface BLb of the bit line BL, and an upper insulating liner 260, which is provided to enclose the side surface of the buried node contact BN. As an example, the lower and upper insulating liners 160 and 260 may be in direct contact with each other without any interface therebetween. However, embodiments of the present inventive concept are not necessarily limited thereto.

The lower insulating liner 160 may be interposed between the bit line BL and the substrate 100. As an example, the lower insulating liner 160 may be interposed between the bit line BL and the insulating substrate 106. The lower insulating liner 160 may separate the bit line BL from the substrate 100. The shielding pattern 140 may be interposed between the lower insulating liner 160 and the insulating substrate 106. The lower insulating liner 160 may extend along the side surface of the bit line BL and in the first direction D1.

The upper insulating liner 260 may extend into regions between the buried node contact BN and the substrate 100 and between the buried node contact BN and the semiconductor layer 200. The upper insulating liner 260 may separate the buried node contact BN from the substrate 100 and the semiconductor layer 200. The upper insulating liner 260 may be provided to enclose a side surface of the lower buried node contact LBN. As an example, the upper insulating liner 260 may be in direct contact with the lower buried node contact LBN. The upper insulating liner 260 may enclose the side surface of the upper buried node contact UBN. As an example, the upper insulating liner 260 may enclose the side surface of the lower portion of the upper buried node contact UBN, but not a side surface of an upper portion of the upper buried node contact UBN. The upper insulating liner 260 may be spaced apart from the upper buried node contact UBN. The lower node capping pattern 280 may be interposed between the upper insulating liner 260 and the upper buried node contact UBN, such as a lower portion of the upper buried node contact UBN.

The insulating liner 60 may be formed of or include an insulating material. As an example, in an embodiment each of the lower and upper insulating liners 160 and 260 may be independently formed of or include at least one of silicon oxide or silicon nitride. However, embodiments of the present inventive concept are not necessarily limited thereto. Each of the lower and upper insulating liners 160 and 260 may be independently a single layer, which is made of a single material, or a composite layer, which is made of two or more materials.

A trench liner 120 may be interposed between the substrate 100 and the bit line BL. As an example, the trench liner 120 may be interposed between the insulating liner 60 and the substrate 100 and between the shielding pattern 140 and the substrate 100. The trench liner 120 may cover the side surface (e.g., lateral side surface) and the bottom surface BLb of the bit line BL. In an embodiment, the trench liner 120 may be formed of or include silicon oxide. However, embodiments of the present inventive concept are not necessarily limited thereto.

A data storage pattern may be provided on the active pattern ACT. In an embodiment, a plurality of data storage patterns may be provided. Each of the data storage patterns may be connected to a corresponding one of the first and second channel patterns CH1 or CH2.

In an embodiment, the data storage pattern may be a capacitor including a bottom electrode, a dielectric layer, and a top electrode. In this embodiment, the semiconductor memory device may be a dynamic random access memory (DRAM) device. In an embodiment, the data storage pattern may include a magnetic tunnel junction pattern. In this embodiment, the semiconductor memory device may be a magnetic random access memory (MRAM) device. In an embodiment, the data storage pattern may be formed of or include a phase-change material or a variable resistance material. In this embodiment, the semiconductor memory device may be a phase-change random access memory (PRAM) device or a resistive random access memory (ReRAM) device. However, embodiments of the present inventive concept are not necessarily limited thereto, and the data storage pattern may include various structures and/or materials which can be used to store data.

In an embodiment, a storage node contact may be provided between the active pattern ACT and the data storage pattern. In an embodiment, a plurality of storage node contacts may be provided. Each of the storage node contacts may be configured to connect a corresponding one of the data storage patterns to a corresponding one of the first and second channel patterns CH1 and CH2. However, embodiments of the present inventive concept are not necessarily limited thereto, and in an embodiment, the data storage pattern may be directly connected to a corresponding one of the first and second channel patterns CH1 and CH2, without the storage node contact.

According to an embodiment of the present inventive concept, the bit line BL may be disposed within the substrate 100. In addition, the active pattern ACT may be located at a level higher than the bit line BL. Thus, a technical limitation in placing the bit lines BL may be reduced, compared with an embodiment in which the bit line BL and the data storage pattern (or the storage node contact) are located at the same or similar level on the active pattern ACT. Consequently, it may be possible to efficiently dispose the bit lines BL, thereby increasing an integration density of the semiconductor device.

In addition, according to an embodiment of the present inventive concept, the bit line BL may be disposed in the insulating substrate 106 of the substrate 100. Furthermore, the shielding pattern 140 may be arranged to enclose the bit line BL. Accordingly, a coupling phenomenon between the bit lines BL may be suppressed, and as a result, the electrical and reliability characteristics of the semiconductor device may be increased.

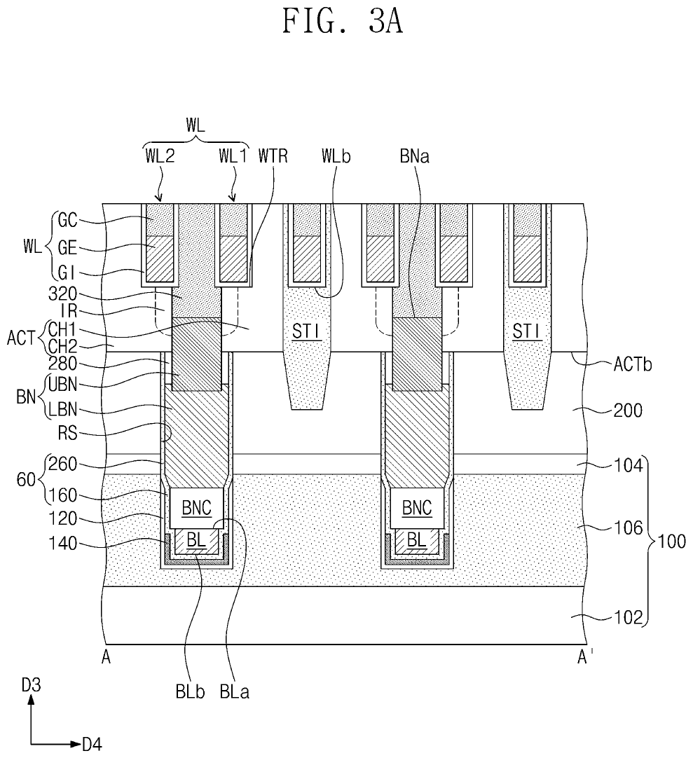

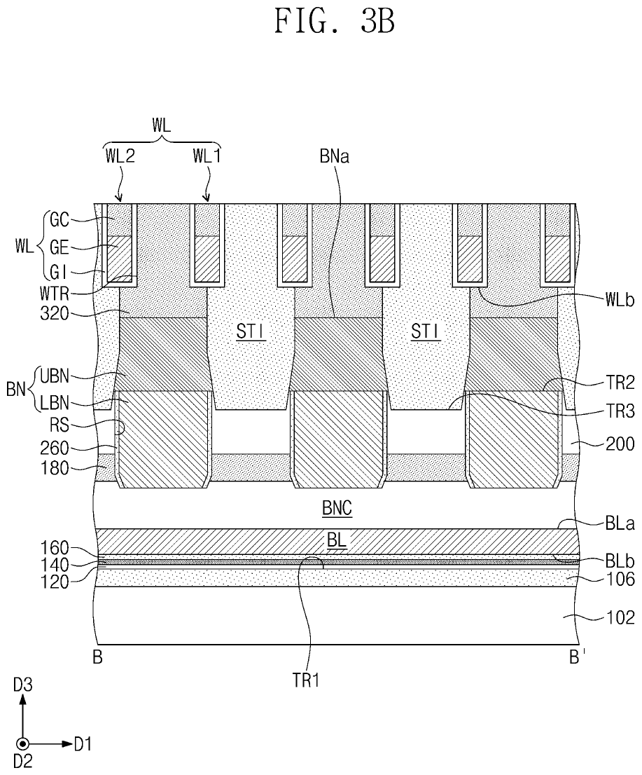

Hereinafter, embodiments of the present inventive concept will be described with reference to FIGS. 3A to 8. In the following description, a previously-described element may be identified by the same reference number without repeating an overlapping description thereof, for concise description.

FIGS. 3A and 3B are cross-sectional views, which are respectively taken along the lines A-A′ and B-B′ of FIG. 1 to illustrate a semiconductor device according to embodiments of the present inventive concept.

Referring to FIGS. 1, 3A, and 3B, a bit line node contact BNC may be provided on (e.g., disposed directly thereon in the third direction D3) the bit line BL. The bit line node contact BNC may cover the top surface of the bit line BL. The bit line node contact BNC may extend in the first direction D1. In an embodiment, a plurality of bit line node contacts BNC may be provided. Each of the bit line node contacts BNC may be provided on a corresponding one of the bit lines BL.

The bit line node contact BNC may be interposed between the bit line BL and the buried node contact BN (e.g., in the third direction D3). The bit line node contact BNC may connect the bit line BL to the buried node contact BN. The insulating liner 60 (e.g., the lower insulating liner 160) may cover a side surface (e.g., a lateral side surface) of the bit line node contact BNC. The insulating liner 60 may extend into a region between the side surface of the bit line node contact BNC and the substrate 100.

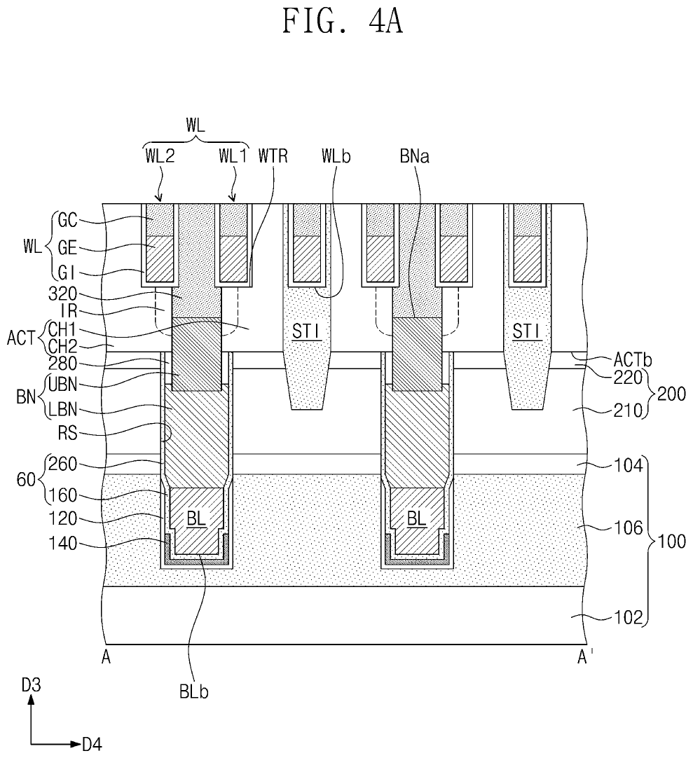

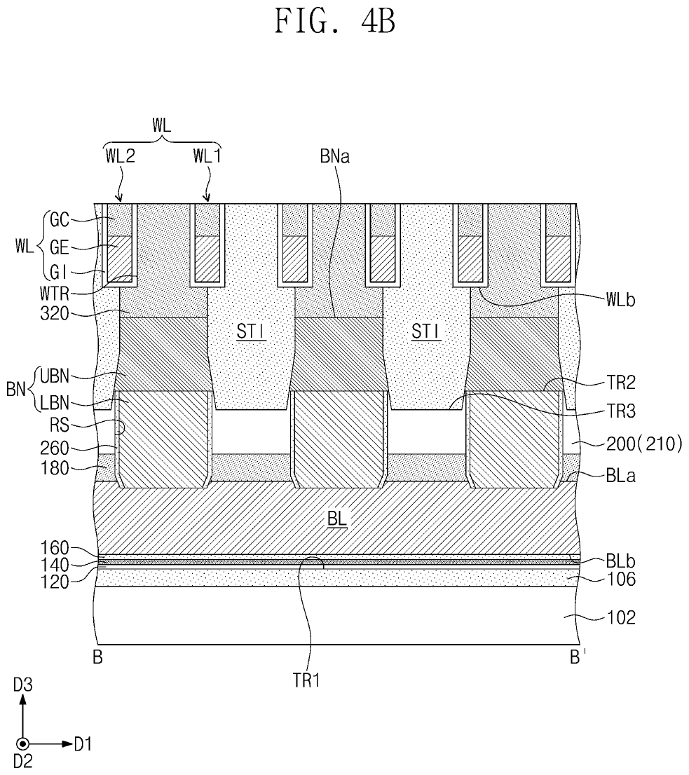

The bit line node contact BNC may be a single layer, which is made of a single material, or a composite layer, which is made of two or more materials. The bit line node contact BNC may be formed of or include a material different from the bit line BL. In an embodiment, the bit line node contact BNC may be formed of or include at least one material selected from doped polysilicon, metallic materials (e.g., Ti, Mo, W, Cu, Co, Al, Ta, Ru, Ir, and so forth), metal nitride materials of the metallic materials, and metal silicide materials of the metallic materials. As an example, the bit line node contact BNC may be a single layer made of polysilicon. As another example, the bit line node contact BNC a composite layer, which is made of a metal nitride material and polysilicon. As still other example, the bit line node contact BNC may be a single layer made of a metal silicide material. However, embodiments of the present inventive concept are not necessarily limited thereto, and in an embodiment, the bit line node contact BNC may be formed of or include one of the materials or any possible combination of the materials. FIGS. 4A and 4B are cross-sectional views, which are respectively taken along the lines A-A′ and B-B′ of FIG. 1 to illustrate a semiconductor device according to embodiments of the present inventive concept.

Referring to FIGS. 1, 4A, and 4B, the semiconductor layer 200 may include a lower semiconductor layer 210 and an upper semiconductor layer 220 on the lower semiconductor layer 210 (e.g., disposed directly thereon in the third direction D3). The upper semiconductor layer 220 may cover the lower semiconductor layer 210. The upper semiconductor layer 220 may be interposed between the lower semiconductor layer 210 and the active pattern ACT. In an embodiment, a top surface of the upper semiconductor layer 220 may be located at substantially the same level as the top surface of the lower node capping pattern 280 and may be coplanar with the top surface of the lower node capping pattern 280 (e.g., in the third direction D3). In an embodiment, a thickness of the upper semiconductor layer 220 in the third direction D3 may be less than a thickness of the lower semiconductor layer 210. As an example, in an embodiment the thickness of the upper semiconductor layer 220 in the third direction D3 may range from about 50 Å to about 100 Å.

Each of the lower and upper semiconductor layers 210 and 220 may be formed of or include a semiconductor material. The upper semiconductor layer 220 may be formed of or include a material different from the lower semiconductor layer 210. In an embodiment, the lower semiconductor layer 210 may be a silicon-containing layer, and the upper semiconductor layer 220 may be a layer containing silicon germanium. In an embodiment, a germanium concentration of the silicon germanium may be in a range of about 10% to about 30%.

Since the upper semiconductor layer 220 is provided between the lower semiconductor layer 210 and the active pattern ACT (e.g., in the third direction D3), there may be an offset in an active valance band between the lower semiconductor layer 210 and the active pattern ACT. Therefore, holes may be prevented from being accumulated in the first and second channel patterns CH1 and CH2 of the active pattern ACT, and as a result, the electrical and reliability characteristics of the semiconductor device may be increased.

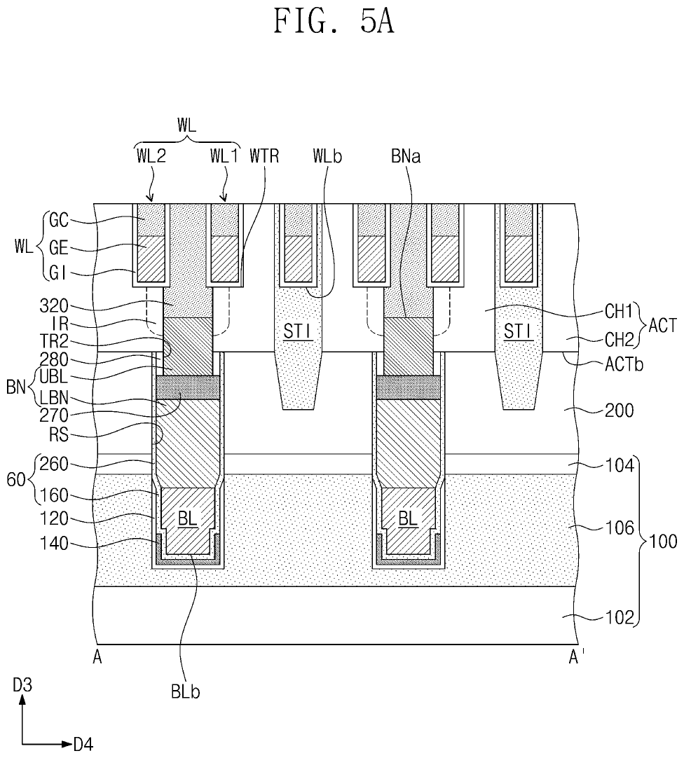

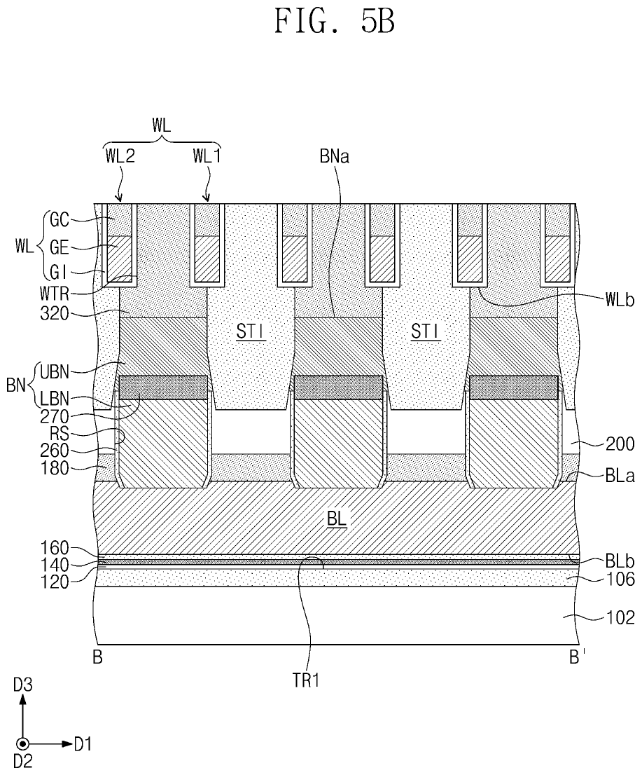

FIGS. 5A and 5B are cross-sectional views, which are respectively taken along the lines A-A′ and B-B′ of FIG. 1 to illustrate a semiconductor device according to an embodiment of the present inventive concept.

Referring to FIGS. 1, 5A, and 5B, a buried ohmic pattern 270 may be provided between (e.g., disposed directly therebetween in the third direction D3) the lower buried node contact LBN and the upper buried node contact UBN. The buried ohmic pattern 270 may enable the lower buried node contact LBN and the upper buried node contact UBN to form an ohmic contact structure. In an embodiment, the lower buried node contact LBN may be formed of or include polysilicon, and the upper buried node contact UBN may be formed of or include a metallic material. In this embodiment, the buried ohmic pattern 270 may be formed of or include a metal silicide material. In an embodiment of FIG. 5A, the buried ohmic pattern 270 is illustrated to have the same width as the lower buried node contact LBN. However, embodiments of the present inventive concept are not necessarily limited thereto. For example, the width of the buried ohmic pattern 270 may be variously changed.

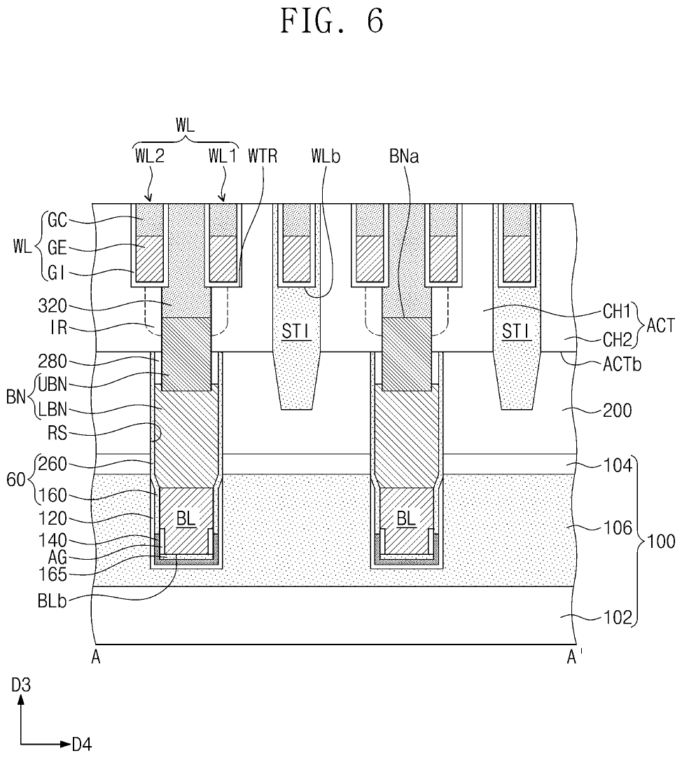

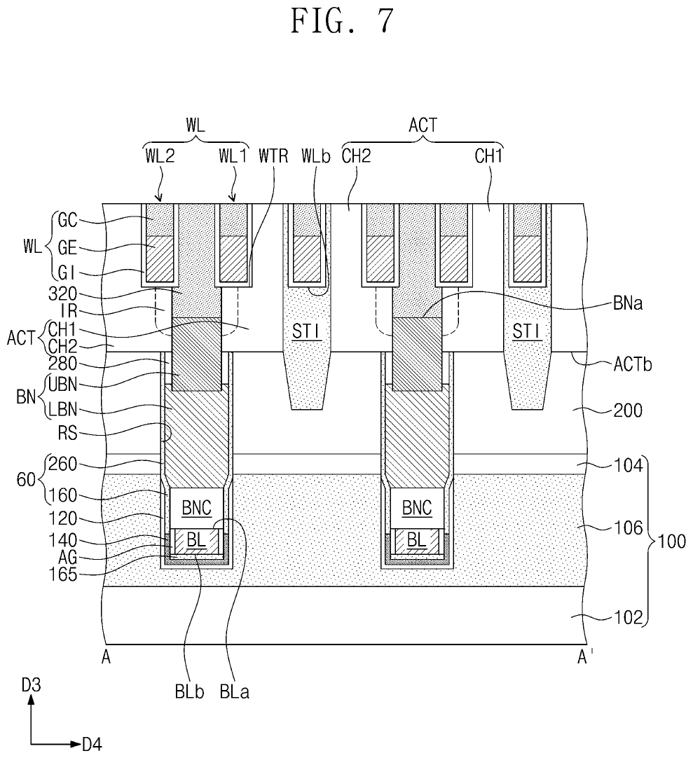

FIGS. 6 and 7 are cross-sectional views, which are respectively taken along the line A-A′ of FIG. 1 to illustrate a semiconductor device according to embodiments of the present inventive concept.

Referring to FIGS. 6 and 7, an air gap AG may be provided on the side surface of the bit line BL, such as disposed directly on a lower lateral side surface of the bit line BL. In the present specification, the air gap AG may mean an empty space that is formed of an air layer or is in a substantially vacuum state. The air gap AG on the side surface of the bit line BL may be provided in a region extending along the first direction D1. The air gap AG may be defined between (e.g., directly therebetween) the side surface of the bit line BL and the shielding pattern 140. In an embodiment, a portion of the insulating liner 60 may be exposed to the air gap AG. However, embodiments of the present inventive concept are not necessarily limited thereto.

A sacrificial pattern 165 may be provided on (e.g., disposed directly thereon) the bottom surface BLb of the bit line BL and the bottom surface of the air gap AG. The sacrificial pattern 165 may be interposed between (e.g., directly therebetween) the bottom surface BLb of the bit line BL and the shielding pattern 140. A portion of the sacrificial pattern 165 may be exposed to the air gap AG. In an embodiment, a portion of the sacrificial pattern 165, such as a portion of the top surface of the sacrificial pattern 165, may be exposed to a bottom of the air gap AG. In an embodiment, the sacrificial pattern 165 may be formed of or include a material having an etch selectivity with respect to the trench liner 120. As an example, the sacrificial pattern 165 may be formed of or include silicon nitride, and the insulating substrate 106 may be formed of or include silicon oxide. However, embodiments of the present inventive concept are not necessarily limited thereto.

As an example, the topmost portion of the air gap AG may be formed to expose the bit line BL, as shown in FIG. 6. As another example, the topmost portion of the air gap AG may be formed to expose the bit line node contact BNC, such a as a portion of a lower surface of the bit line node contact BNC as shown in FIG. 7. In an embodiment, the air gap AG may be extend further into a region between the bit line node contact BNC and the insulating liner 60.

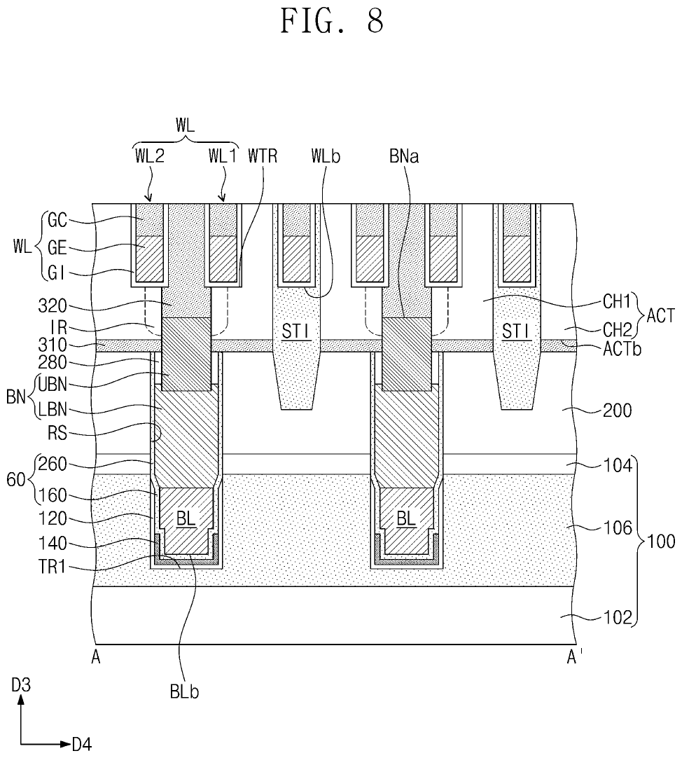

FIG. 8 is a cross-sectional view, which is respectively taken along the line A-A′ of FIG. 1 to illustrate a semiconductor device according to an embodiment of the present inventive concept.

Referring to FIGS. 1 and 8, an interlayer insulating layer 310 may be provided on the semiconductor layer 200 (e.g., disposed directly thereon in the third direction D3). The interlayer insulating layer 310 may cover a top surface of the semiconductor layer 200 and a top surface of the insulating liner 60. The interlayer insulating layer 310 may be interposed between (e.g., interposed directly therebetween) the semiconductor layer 200 and the active pattern ACT. In an embodiment in which the interlayer insulating layer 310 is provided, the active pattern ACT may be formed of or include an oxide semiconductor material (e.g., IGZO). However, embodiments of the present inventive concept are not necessarily limited thereto. The interlayer insulating layer 310 may be formed of or include an insulating material. As an example, the interlayer insulating layer 310 may be formed of or include silicon oxide.

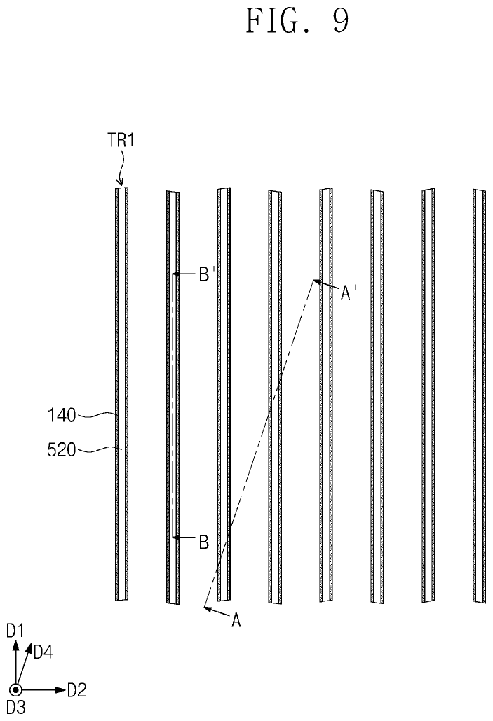

Hereinafter, a method of fabricating a semiconductor device according to embodiments of the present inventive concept will be described in more detail with reference to FIGS. 9 to 26. In the following description, a previously-described element may be identified by the same reference number without repeating an overlapping description thereof, for concise description.

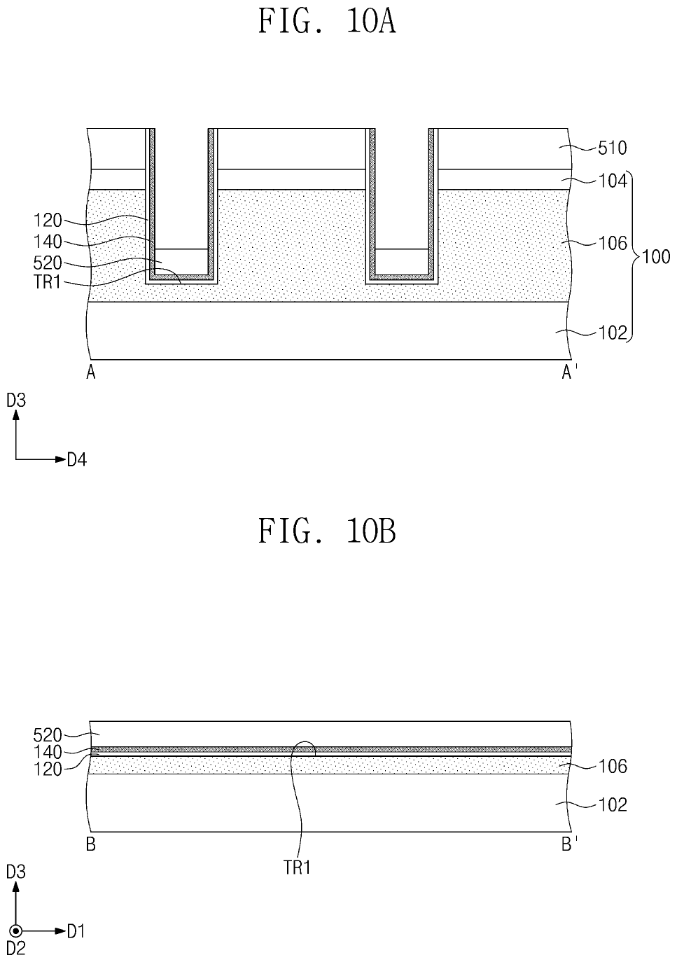

FIGS. 9 to 20B are diagrams illustrating a method of fabricating a semiconductor device, according to an embodiment of the present inventive concept. In detail, FIGS. 9, 11, 13, 15, 17, and 19 are plan views illustrating the fabrication method, according to embodiments of the present inventive concept. FIGS. 10A, 12A, 14A, 16A, 18A, and 20A are cross-sectional views taken along lines A-A′ of FIGS. 9, 11, 13, 15, 17, and 19, respectively. FIGS. 10B, 12B, 14B, 16B, 18B, and 20B are cross-sectional views taken along lines B-B′ of FIGS. 9, 11, 13, 15, 17, and 19, respectively.

Referring to FIGS. 9, 10A, and 10B, the substrate 100 may be provided. The substrate 100 may include the lower substrate 102, the upper substrate 104, and the insulating substrate 106 therebetween.

A mask pattern 510 may be provided on the substrate 100 (e.g., disposed directly thereon in the third direction D3). The mask pattern 510 may include a plurality of line patterns. Each of the line patterns may extend along the first direction D1. The line patterns may be spaced apart from each other in the second direction D2. Thus, a mask trench region may be formed between adjacent ones of the line patterns.

The substrate 100 may be etched using the mask pattern 510 as an etch mask. The etching process may be performed to etch the upper substrate 104 and the insulating substrate 106, but not the lower substrate 102. A first trench region TR1 may be formed in the substrate 100. In an embodiment, a plurality of first trench regions TR1 may be provided. Each of the first trench regions TR1 may extend along the first direction D1. The first trench regions TR1 may be spaced apart from each other in the second direction D2. The upper substrate 104 and the insulating substrate 106 may be exposed to the outside through an inner side surface of the first trench region TR1. The insulating substrate 106 may also be exposed to the outside through an inner bottom surface of the first trench region TR1. In an embodiment, a portion of the mask pattern 510 may remain after the etching process.

The trench liner 120 and the shielding pattern 140 may be formed on an inner surface of the first trench region TR1. The trench liner 120 may be conformally formed on the inner surface of the first trench region TR1, and the shielding pattern 140 may conformally cover the trench liner 120.

Thereafter, an etch prevention pattern 520 may be formed in a lower portion of the first trench region TR1. The etch prevention pattern 520 may cover portions of the trench liner 120 and the shielding pattern 140 on the inner bottom surface of the first trench region TR1. In an embodiment, the formation of the etch prevention pattern 520 may include forming an etch stop layer to fill the first trench region TR1 and removing an upper portion of the etch stop layer to form the etch prevention pattern 520. As an example, the removing of the upper portion of the etch stop layer may include performing an etch-back process on the etch stop layer. However, embodiments of the present inventive concept are not necessarily limited thereto. In the lower portion of the first trench region TR1, the etch prevention pattern 520 may extend along the first direction D1.

In the process of forming the trench liner 120 and the shielding pattern 140, a top surface of the mask pattern 510 may be covered with the trench liner 120 and the shielding pattern 140. In an embodiment, the trench liner 120 and the shielding pattern 140 may be removed from the top surface of the mask pattern 510 during, before, or after the formation of the etch prevention pattern 520.

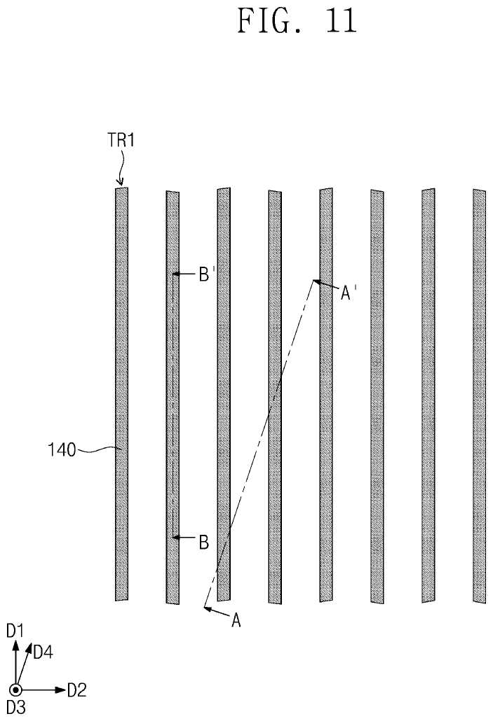

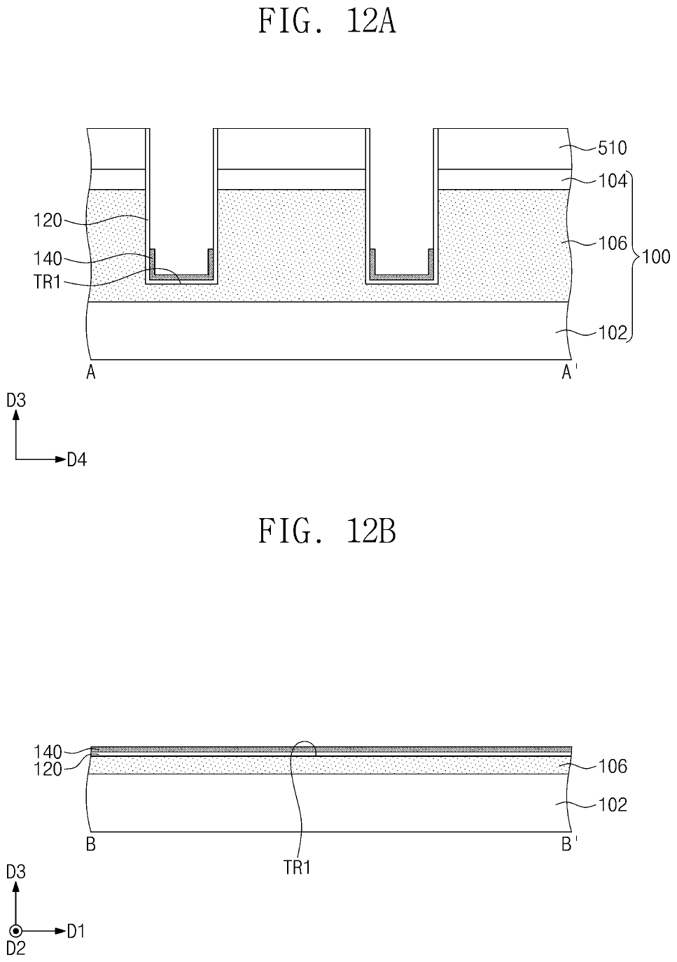

Referring to FIGS. 11, 12A, and 12B, the trench liner 120 and the shielding pattern 140 may be removed from an upper portion of the first trench region TR1. In an embodiment, the removal process may include etching the trench liner 120 and the shielding pattern 140. In an embodiment, the etching process may be a wet etching process. However, embodiments of the present inventive concept are not necessarily limited thereto. During this process, the etch prevention pattern 520 may prevent the trench liner 120 and the shielding pattern 140 from being removed from the lower portion of the first trench region TR1. Thus, the trench liner 120 and the shielding pattern 140 may remain in the lower portion of the first trench region TR1. In an embodiment, the etch prevention pattern 520 may be removed with the shielding pattern 140 in the upper portion of the first trench region TR1.

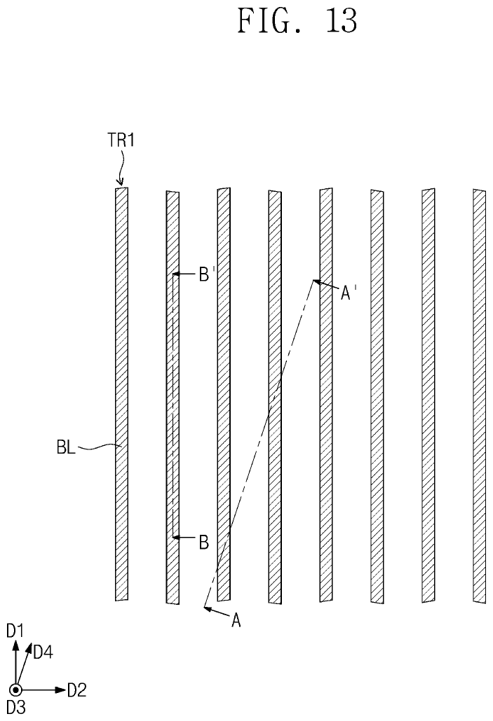

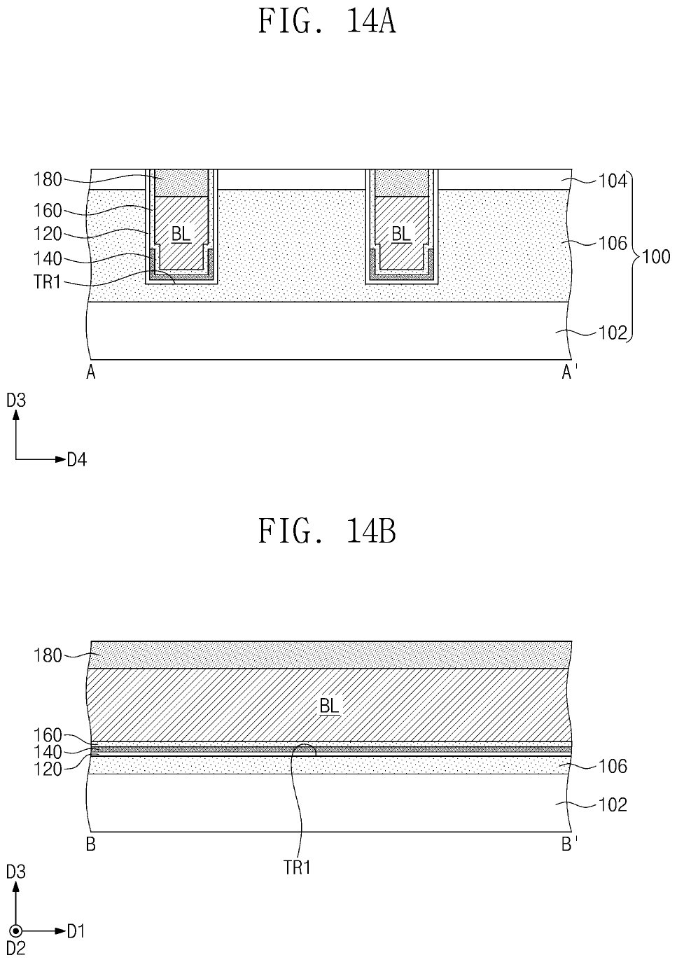

Referring to FIGS. 13, 14A, and 14B, the lower insulating liner 160 may be formed in the first trench region TR1. The lower insulating liner 160 may conformally cover the inner surface of the first trench region TR1. As an example, the lower insulating liner 160 may conformally cover the trench liner 120 and the shielding pattern 140, in the lower portion of the first trench region TR1. In an embodiment, the lower insulating liner 160 may further extend to a region on the top surface of the substrate 100. In an embodiment, the formation of the lower insulating liner 160 may include performing a physical vapor deposition (PVD) process, a chemical vapor deposition (CVD) process, or an atomic layer deposition (ALD) process. However, embodiments of the present inventive concept are not necessarily limited thereto.

The bit line BL may be formed in the first trench region TR1. In an embodiment, the formation of the bit line BL may include forming a bit line layer to fill the first trench region TR1 and cover the top surface of the substrate 100 and removing an upper portion of the bit line layer to form the bit line BL in the first trench region TR1. During the process of removing the upper portion of the bit line layer, the lower insulating liner 160 may be further removed from the top surface of the substrate 100. In an embodiment, the removal process may include performing an etch-back process.

The bit line capping pattern 180 may be formed on the bit line BL (e.g., formed directly thereon in the third direction D3). The bit line capping pattern 180 may fill a remaining portion of the first trench region TR1. In an embodiment, the formation of the bit line capping pattern 180 may include forming a bit line capping layer and removing an upper portion of the bit line capping layer to form the bit line capping pattern 180 in the first trench region TR1. In an embodiment, the process of removing the upper portion of the bit line capping layer may include an etch-back process or a polishing process. The mask pattern 510 may be removed during, before, or after the formation of the lower insulating liner 160, the bit line BL, and the bit line capping pattern 180.

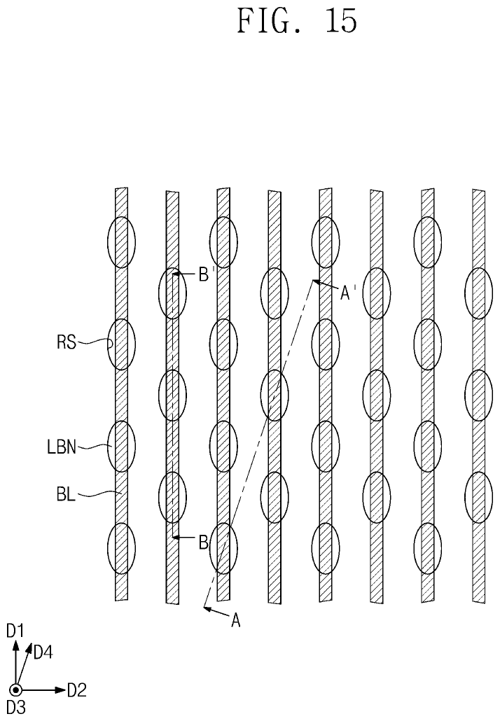

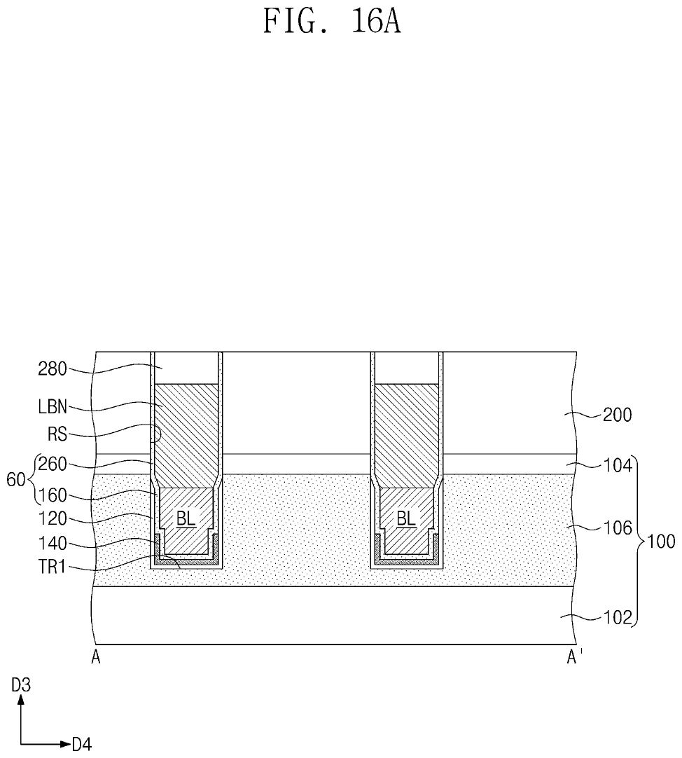

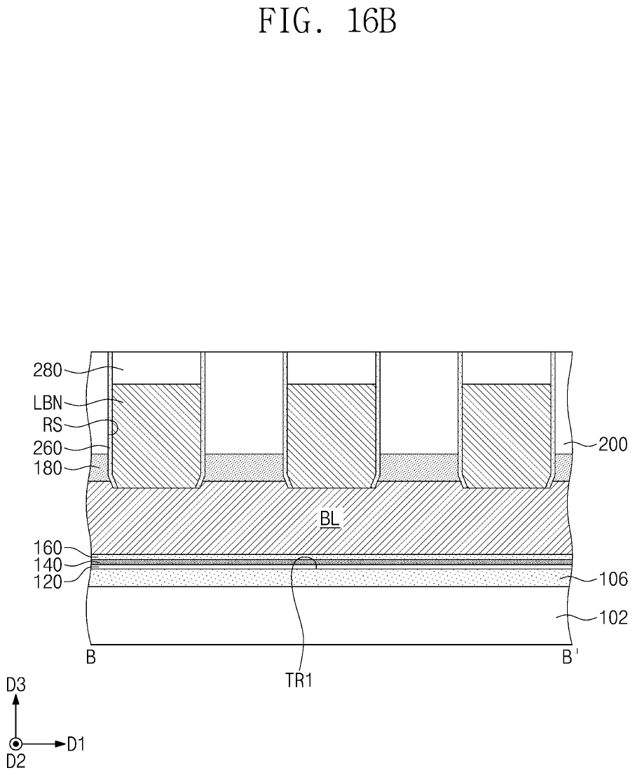

Referring to FIGS. 15, 16A, and 16B, the semiconductor layer 200 may be formed on the substrate 100 (e.g., formed directly thereon in the third direction D3). The semiconductor layer 200 may cover the substrate 100 and the bit line capping pattern 180. In an embodiment, the formation of the semiconductor layer 200 may include performing a selective epitaxial growth (SEG) process. In an embodiment, a top surface of the upper substrate 104 may be used as a seed layer, in the SEG process.

A recess region RS may be formed in the semiconductor layer 200. The recess region RS may be disposed to penetrate the semiconductor layer 200 and the bit line capping pattern 180 in the third direction D3. Thus, the bit line BL may be exposed to the outside through a bottom surface of the recess region RS.

In an embodiment, a plurality of recess regions RS may be provided. The recess regions RS may be spaced apart from each other in the first and second directions D1 and D2. A column of the recess regions RS, which are arranged parallel to the first direction D1, may be vertically overlapped with one of the bit lines BL.

The upper insulating liner 260 may cover an inner surface of the recess region RS. As an example, the upper insulating liner 260 may conformally cover the inner surface of the recess region RS. The upper insulating liner 260 may further cover the top surface of the semiconductor layer 200 and the top surface of the bit line BL. In an embodiment, the formation of the upper insulating liner 260 may include performing a PVD, CVD, or ALD process. However, embodiments of the present inventive concept are not necessarily limited thereto.

Thereafter, the upper insulating liner 260 may be removed from the top surface of the semiconductor layer 200 and the top surface of the bit line BL. As a result of the removal process, the bit line BL may be re-exposed to the outside through the bottom surface of the recess region RS. The upper insulating liner 260, along with the lower insulating liner 160, may constitute the insulating liner 60.

The lower buried node contact LBN may be formed in the recess region RS. In an embodiment, the formation of the lower buried node contact LBN may include forming a lower buried node layer to fill the recess region RS and cover the semiconductor layer 200 and removing an upper portion of the lower buried node layer to form the lower buried node contact LBN. As a result of the removal of the upper portion of the lower buried node layer, the top surface of the lower buried node contact LBN may be recessed from the top surface of the semiconductor layer 200. The lower node capping pattern 280 may then be formed on the lower buried node contact LBN and may fill a remaining portion of the recess region RS.

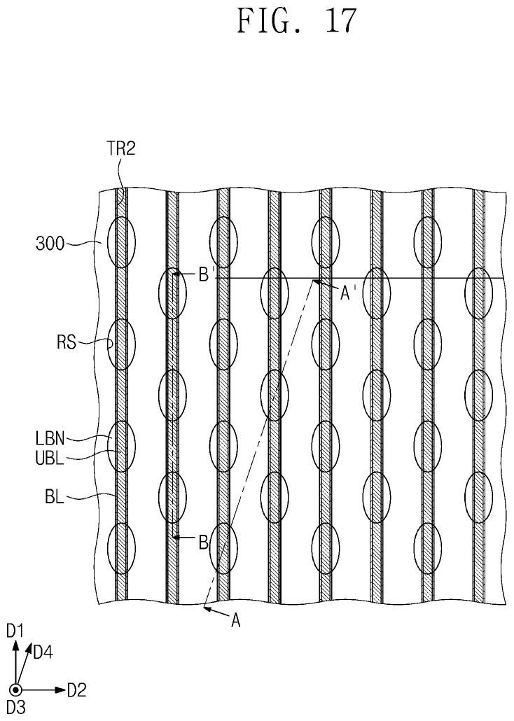

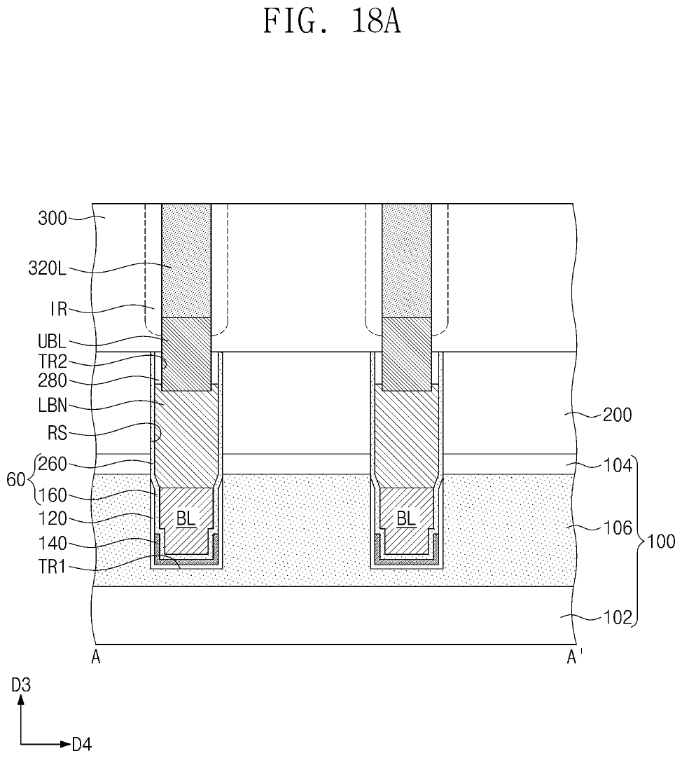

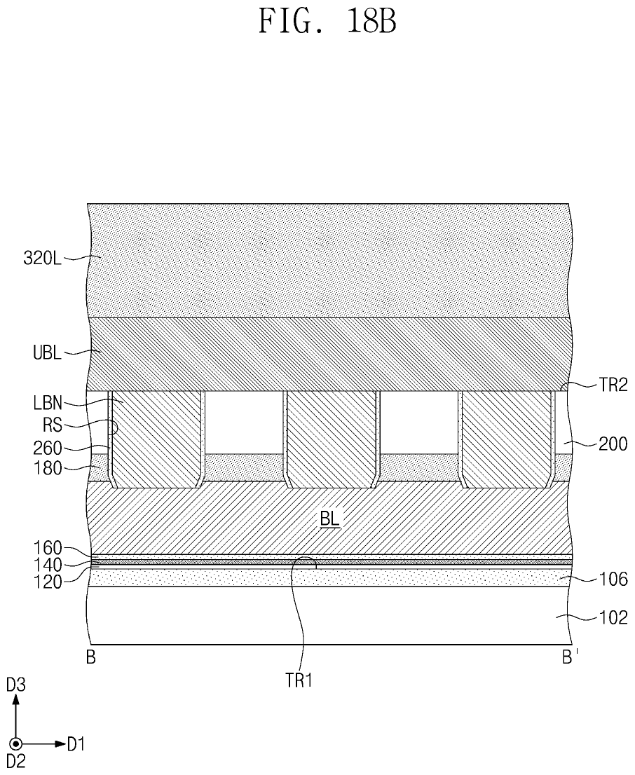

Referring to FIGS. 17, 18A, and 18B, an active layer 300 may be formed on the semiconductor layer 200 (e.g., formed directly thereon in the third direction D3). The active layer 300 may cover the semiconductor layer 200 and the lower node capping pattern 280. In an embodiment, the formation of the active layer 300 may include performing a SEG process. In an embodiment, the top surface of the semiconductor layer 200 may be used as a seed layer, in the SEG process. In an embodiment, the formation of the active layer 300 may include performing a PVD, CVD, or ALD process. However, embodiments of the present inventive concept are not necessarily limited thereto.

A second trench region TR2 may be formed in the active layer 300. The second trench region TR2 may penetrate the active layer 300 in the third direction D3. The second trench region TR2 may further penetrate the lower node capping pattern 280 and the semiconductor layer 200 and may expose the lower buried node contact LBN.

In an embodiment, a plurality of second trench regions TR2 may be provided. Each of the second trench regions TR2 may extend along the first direction D1. The second trench regions TR2 may be spaced apart from each other in the second direction D2. Each of the second trench regions TR2 may be vertically overlapped with a corresponding one of the bit lines BL.

An upper buried node line UBL may be formed in a lower portion of the second trench region TR2. In an embodiment, the formation of the upper buried node line UBL may include forming an upper buried node layer to fill the second trench region TR2 and cover the active layer 300 and removing an upper portion of the upper buried node layer to form the upper buried node line UBL. In an embodiment, a plurality of upper buried node lines UBL may be provided. Each of the upper buried node lines UBL may extend along the first direction D1. The upper buried node lines UBL may be spaced apart from each other in the second direction D2.

The upper buried node line UBL may be connected to (e.g., directly connected thereto) the lower buried node contact LBN. As an example, each of the upper buried node lines UBL may be connected to a column of the lower buried node contacts LBN arranged in the first direction D1. A top surface of the upper buried node line UBL may be formed at a level higher than a bottom surface of the active layer 300. As an example, an upper portion of the upper buried node line UBL may be in direct contact with a lower portion of the active layer 300.

Thereafter, the impurity region IR may be formed in the active layer 300. The impurity region IR may be formed in a region adjacent to a side surface (e.g., lateral side surfaces) of the second trench region TR2. In an embodiment, the formation of the impurity region IR may include an ion implantation process of injecting impurity ions into the active layer 300 through the second trench region TR2. In an embodiment, the ion implantation process may be performed, without an additional mask pattern for the ion injection. Even without providing the additional mask pattern, the impurity ions may be injected into a sidewall of the second trench region TR2 by performing the ion implantation process at a tilted angle. For example, the impurity region IR may be formed through a self-aligned ion implantation process.

An upper node capping line 320L may be formed on (e.g., formed directly thereon) the upper buried node line UBL. The upper node capping line 320L may fill a remaining portion of the second trench region TR2. The upper node capping line 320L may be formed on the upper buried node line UBL and may extend along the first direction D1.

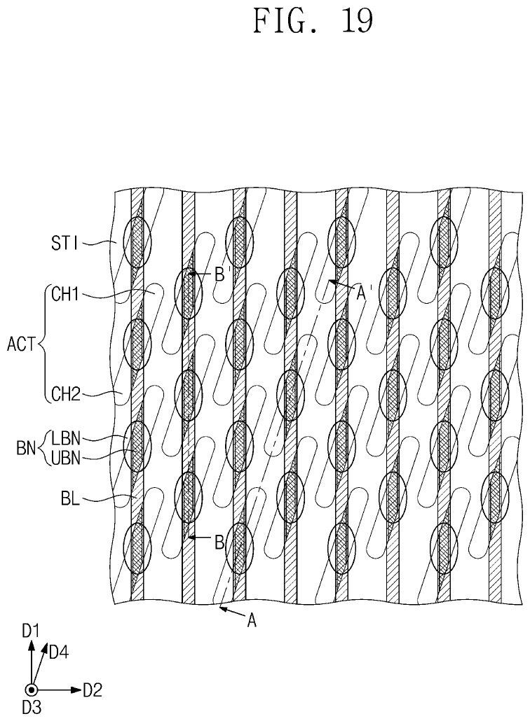

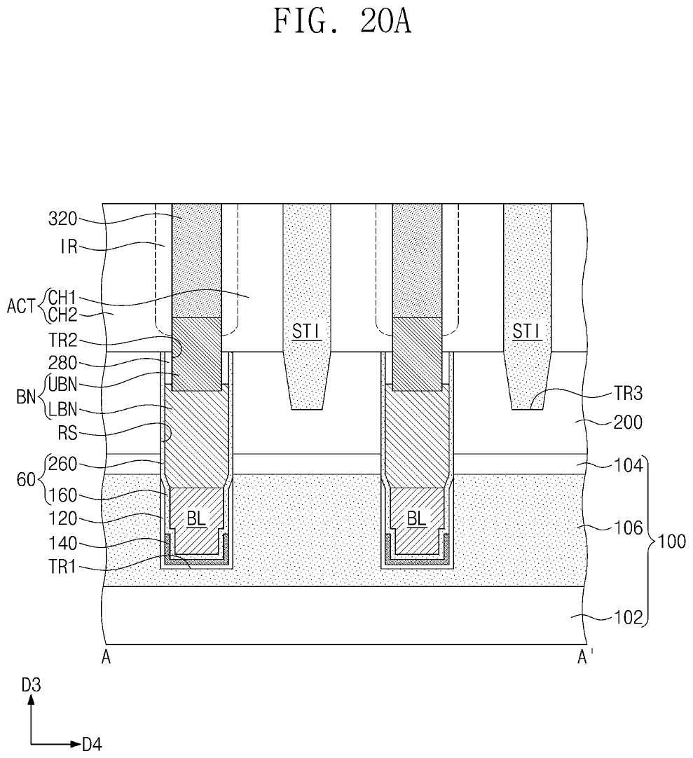

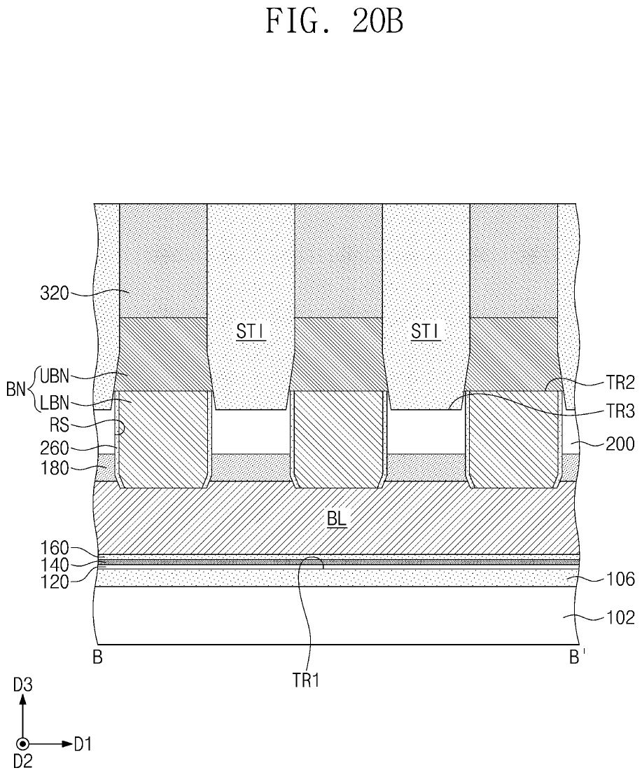

Referring to FIGS. 19, 20A, and 20B, the active patterns ACT may be formed by etching the active layer 300. For example, a third trench region TR3 may be formed, as a result of the etching of the active layer 300, and an unetched portion of the active layer 300 may be defined as the active patterns ACT.

In an embodiment, when the etching process is performed on the active layer 300, the upper node capping line 320L and the upper buried node line UBL may also be etched to form a plurality of upper node capping patterns 320, which are separated from each other, and a plurality of separated upper buried node contacts UBN, which are separated from each other. The upper buried node contacts UBN may be connected to (e.g., directly connected thereto) the lower buried node contacts LBN, respectively, thereby constituting the buried node contact BN. Each of the active patterns ACT may include the first and second channel patterns CH1 and CH2, which are spaced apart from each other with the buried node contact BN interposed therebetween.

In an embodiment, the third trench region TR3 may extend to a level that is lower than the top surface of the semiconductor layer 200. A bottom surface of the third trench region TR3 may be located at a level that is lower than the top surface of the semiconductor layer 200. As an example, the bottom surface of the third trench region TR3 may be formed at a level that is lower than the top surface of the lower buried node contact LBN.

In an embodiment, the device isolation pattern STI may then be formed in the third trench region TR3. The device isolation pattern STI may fill the third trench region TR3. The device isolation pattern STI may enclose the active patterns ACT.

Referring back to FIGS. 1, 2A, and 2B, the word line WL may be formed to cross the active patterns ACT and the device isolation pattern STI. In an embodiment, the formation of the word line WL may include forming a word line trench region WTR to cross the active patterns ACT and the device isolation pattern STI and filling the word line trench region WTR with the word line WL. In an embodiment, the filling of the word line WL may include conformally forming the gate insulating pattern GI on an inner surface of the word line trench region WTR, filling an inner space of the word line trench region WTR with a conductive layer, removing an upper portion of the conductive layer to form the gate electrode GE, and forming the gate capping pattern GC on the gate electrode GE to fill a remaining portion of the word line trench region WTR.

Thereafter, a data storage pattern and/or a storage node contact may be further formed using a conventional semiconductor fabrication method.

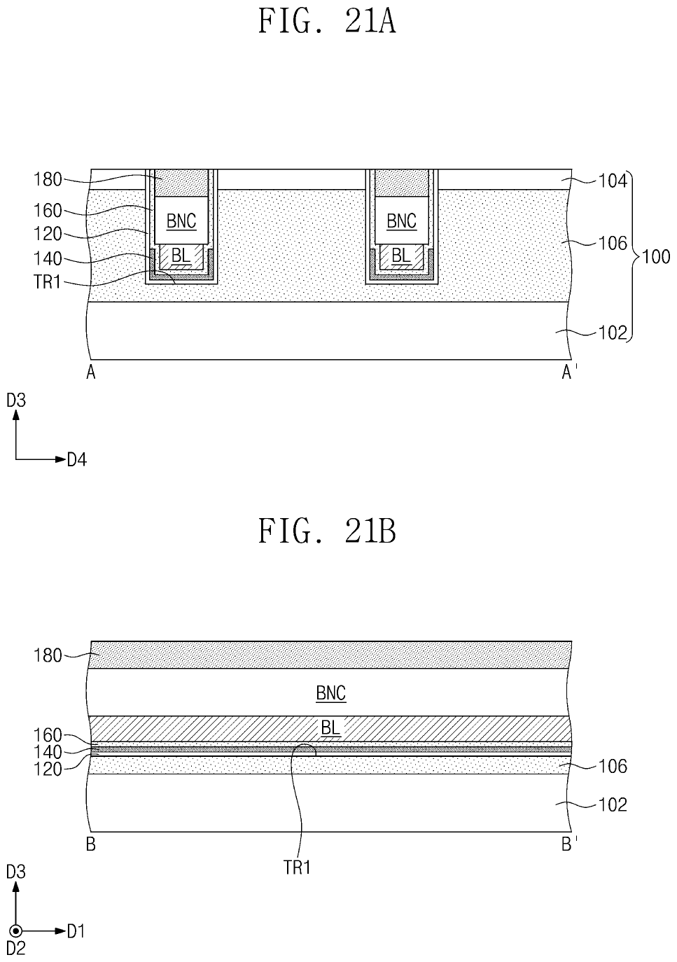

FIGS. 21A and 21B are cross-sectional views, which are respectively taken along lines A-A′ and B-B′ of FIG. 13 to illustrate a method of fabricating a semiconductor device, according to embodiments of the present inventive concept.

Referring to FIGS. 21A and 21B, the bit line node contact BNC may be further formed, after the formation of the bit line BL described with reference to FIGS. 13, 14A, and 14B. In an embodiment, the formation of the bit line node contact BNC may include forming a bit line node layer to fill the first trench region TR1 and cover the top surface of the substrate 100 and removing an upper portion of the bit line node layer to form the bit line node contact BNC in the first trench region TR1.

The semiconductor device of FIGS. 3A and 3B may then be fabricated using the afore-described fabrication method.

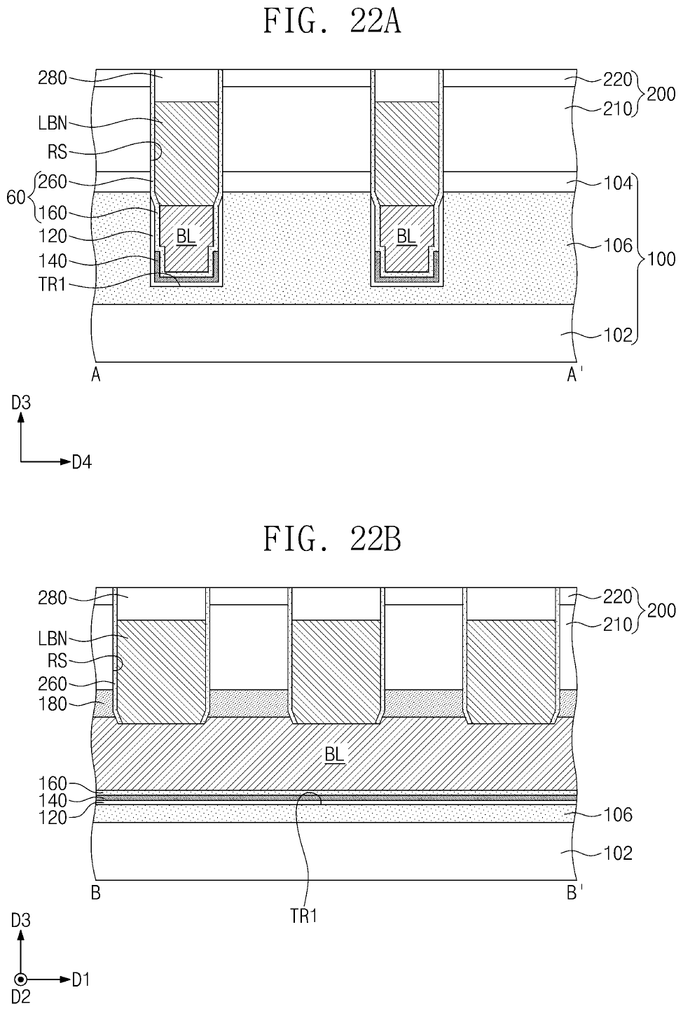

FIGS. 22A and 22B are cross-sectional views, which are respectively taken along lines A-A′ and B-B′ of FIG. 15 to illustrate a method of fabricating a semiconductor device, according to embodiments of the present inventive concept.

Referring to FIGS. 22A and 22B, the lower and upper semiconductor layers 210 and 220 may be sequentially formed, when the semiconductor layer 200 described with reference to FIGS. 15, 16A, and 16B is formed. As an example, in an embodiment the formation of the lower semiconductor layer 210 may include performing a SEG process, in which a top surface of the upper substrate 104 is used as a seed layer. The formation of the upper semiconductor layer 220 may include performing a SEG process, in which a top surface of the lower semiconductor layer 210 is used as a seed layer. However, embodiments of the present inventive concept are not necessarily limited thereto.

Thereafter, the semiconductor device of FIGS. 4A and 4B may be fabricated using the afore-described fabrication method.

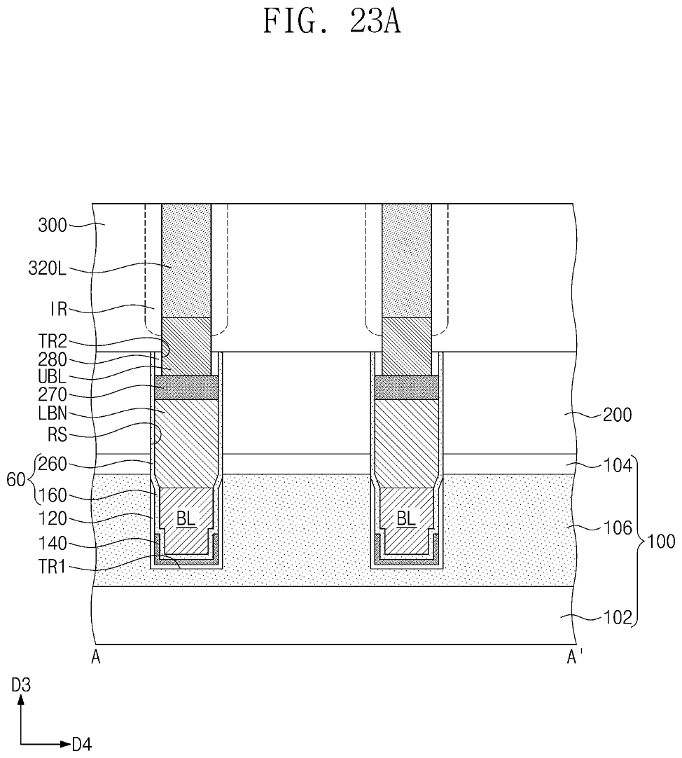

FIGS. 23A and 23B are cross-sectional views, which are respectively taken along lines A-A′ and B-B′ of FIG. 17 to illustrate a method of fabricating a semiconductor device, according to embodiments of the present inventive concept.

Referring to FIGS. 23A and 23B, the buried ohmic pattern 270 may be formed, after the formation of the lower buried node contact LBN described with reference to FIGS. 15, 16A, and 16B.

In an embodiment, the buried ohmic pattern 270 may be formed using various methods and during different stages of the fabrication process. As an example, the buried ohmic pattern 270 may be formed on the lower buried node contact LBN before the formation of the upper buried node line UBL. As another example, the buried ohmic pattern 270 may be formed as a result of a reaction between the lower buried node contact LBN and the upper buried node line UBL, after the formation of the upper buried node line UBL. However, embodiments of the present inventive concept are not necessarily limited thereto, and in an embodiment, the buried ohmic pattern 270 may be formed using various methods which can be tried by a skilled person in this art.

Thereafter, the semiconductor device of FIGS. 5A and 5B may be fabricated using the afore-described fabrication method.

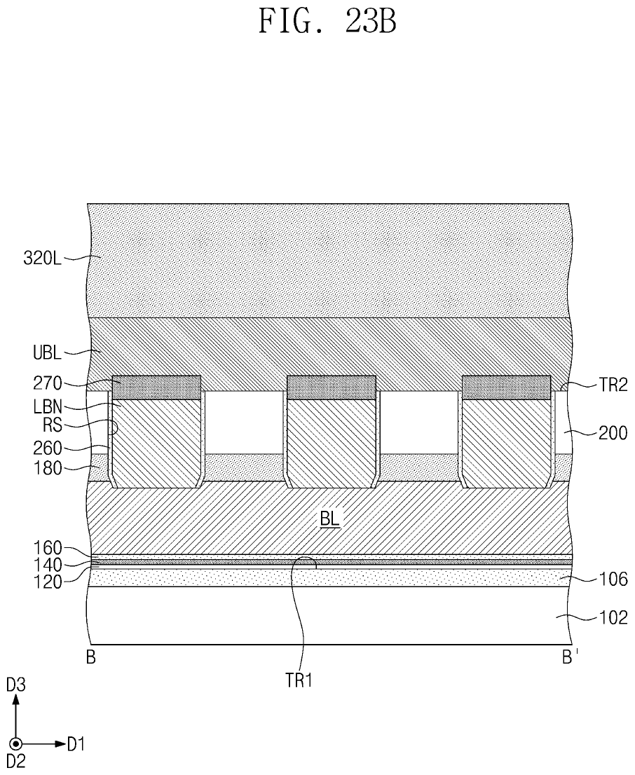

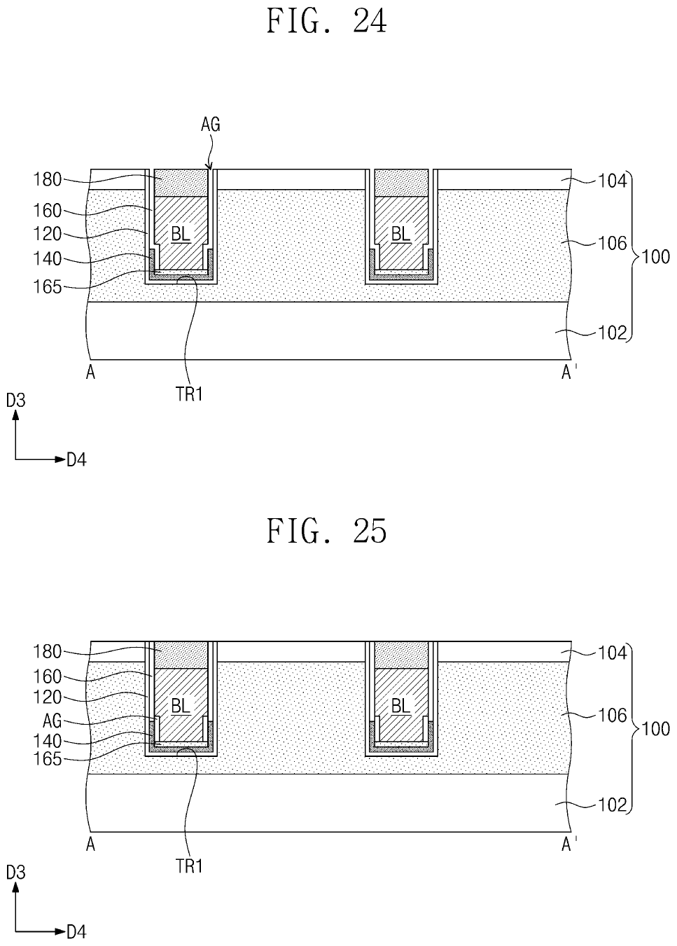

FIGS. 24 and 25 are cross-sectional views illustrating a method of fabricating a semiconductor device, according to embodiments of the present inventive concept.

Referring to FIG. 24, in an embodiment a sacrificial liner may be formed before the formation of the lower insulating liner 160 of FIGS. 14A and 14B. The sacrificial liner may have structural features, which are the same as or similar to those of the lower insulating liner 160. The sacrificial liner may be formed of or include a material having an etch selectivity with respect to the trench liner 120. The bit line BL and the bit line capping pattern 180 may be sequentially formed, after the formation of the sacrificial liner.

After the formation of the bit line capping pattern 180, the topmost surface of the sacrificial liner may be exposed to the outside. A removal process on the sacrificial liner may be performed through the exposed topmost surface of the sacrificial liner. In an embodiment, the removal process may include a wet etching process. As a result of the removal process, the sacrificial liner may be removed from the side surface (e.g., lateral side surface) of the bit line BL and the side surface of the bit line capping pattern 180 to form the air gap AG. After the removal process, a portion of the sacrificial liner may remain between the bottom surface of the bit line BL and the shielding pattern 140 to form the sacrificial pattern 165. In an embodiment, the air gap AG may extend to a region on the side surface (e.g., lateral side surface) of the bit line BL and the side surface of the bit line capping pattern 180 and may be exposed to the outside of the substrate 100.

Referring to FIG. 25, the lower insulating liner 160 may be formed to stop a top entrance of the air gap AG. The lower insulating liner 160 may be formed on a side surface of an upper portion of the bit line BL and the side surface of the bit line capping pattern 180. The entirety of the air gap AG may not be filled with the lower insulating liner 160. For example, the air gap AG may remain on a side surface (e.g., lateral side surface) of a lower portion of the bit line BL. In an embodiment, the formation of the lower insulating liner 160 may include forming the lower insulating liner 160 to stop the top entrance of the air gap AG and cover the substrate 100 and removing the lower insulating liner 160 from the top surface of the substrate 100.

Thereafter, the semiconductor device of FIG. 6 may be fabricated using the afore-described fabrication method. However, in an embodiment in which the bit line node contact BNC is further formed after the formation of the bit line BL, the semiconductor device may be formed to have the structure of FIG. 7.

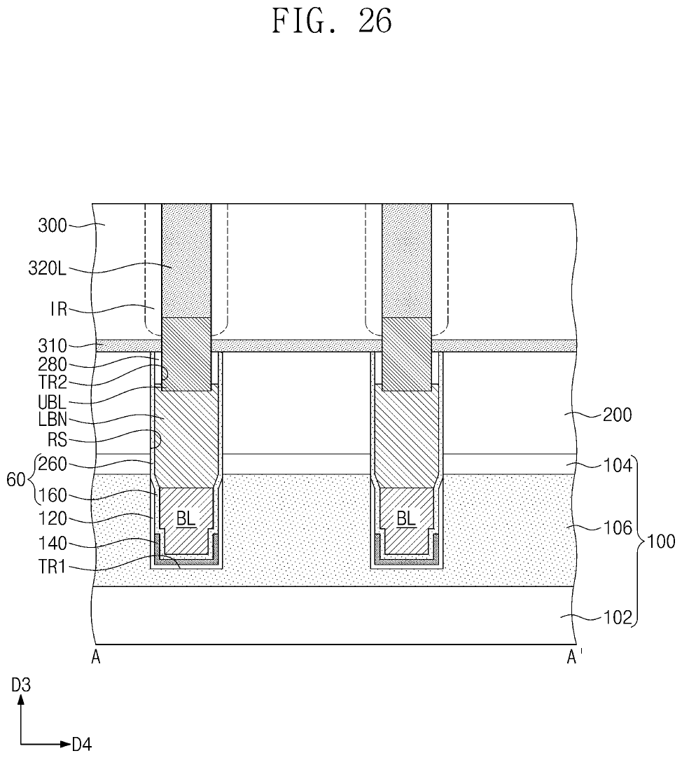

FIG. 26 is a cross-sectional view illustrating a method of fabricating a semiconductor device according to an embodiment of the present inventive concept.

Referring to FIG. 26, the interlayer insulating layer 310 may be formed before the formation of the active layer 300 described with reference to FIG. 18A. The interlayer insulating layer 310 may be formed to cover the top surface of the semiconductor layer 200 and the top surface of the insulating liner 60. The active layer 300 may then be formed to cover the interlayer insulating layer 310. In an embodiment, the active layer 300 may be formed by performing a PVD, CVD, or ALD process. However, embodiments of the present inventive concept are not necessarily limited thereto.

Thereafter, the semiconductor device of FIG. 8 may be fabricated using the afore-described fabrication method.

According to an embodiment of the present inventive concept, it may be possible to reduce a limitation in disposing a plurality of bit lines. Thus, the bit lines may be efficiently disposed, and as a result, an integration density of a semiconductor device may be increased.

In addition, an insulating substrate and a shielding pattern may be provided to enclose the bit line, and thus, a coupling phenomenon between the bit lines may be suppressed. As a result, it may be possible to increase electrical and reliability characteristics of the semiconductor device.

While non-limiting embodiments of the present inventive concept have been particularly shown and described, it will be understood by one of ordinary skill in the art that variations in form and detail may be made therein without departing from the spirit and scope of the present inventive concept.

What is claimed is:

1. A semiconductor device, comprising:
a substrate including an insulating substrate;
a semiconductor layer on the substrate;
an active pattern on the semiconductor layer;
a bit line disposed in the insulating substrate, the bit line extending along a first direction parallel to a bottom surface of the substrate;
a buried node contact penetrating the semiconductor layer in a direction perpendicular to the bottom surface of the substrate; and
a word line penetrating the active pattern in a second direction that is parallel to the bottom surface of the substrate and crosses the first direction,
wherein the active pattern is connected to the bit line through the buried node contact, and
a top surface of the buried node contact is located at a level higher than a bottom surface of the active pattern.

2. The semiconductor device of claim 1, wherein the buried node contact comprises:
a lower buried node contact and an upper buried node contact; and
the lower buried node contact is spaced apart from the active pattern.

3. The semiconductor device of claim 2, wherein the lower buried node contact is connected to the active pattern by the upper buried node contact.

4. The semiconductor device of claim 2, further comprising:
a device isolation pattern disposed on the semiconductor layer, the device isolation pattern enclosing the active pattern,
wherein a bottom surface of the device isolation pattern is located at a level lower than a top surface of the lower buried node contact.

5. The semiconductor device of claim 2, further comprising an insulating liner enclosing a side surface of the lower buried node contact.

6. The semiconductor device of claim 2, further comprising a buried ohmic pattern between the lower buried node contact and the upper buried node contact.

7. The semiconductor device of claim 1, wherein the active pattern comprises at least one compound selected from silicon and IGZO.

8. The semiconductor device of claim 1, further comprising:
a bit line node contact disposed between the bit line and the buried node contact, the bit line node contact extends along the first direction.

9. The semiconductor device of claim 1, wherein:
the semiconductor layer comprises a lower semiconductor layer and an upper semiconductor layer; and
the upper semiconductor layer includes a material different from the lower semiconductor layer.

10. The semiconductor device of claim 1, further comprising a shielding pattern disposed between the insulating substrate and the bit line, the shielding pattern enclosing at least a portion of the bit line.

11. The semiconductor device of claim 10, wherein a topmost surface of the shielding pattern is located at a level higher than a bottom surface of the bit line.

12. The semiconductor device of claim 1, further comprising an air gap between the insulating substrate and a side surface of the bit line.

13. A semiconductor device, comprising:
a substrate including an insulating substrate;
a first channel pattern and a second channel pattern on the substrate;
a bit line disposed in the insulating substrate, the bit line extends along a first direction parallel to a bottom surface of the substrate;
a first word line penetrating the first channel pattern in a second direction that is parallel to the bottom surface of the substrate and crosses the first direction; and
a second word line penetrating the second channel pattern in the second direction,
wherein a topmost surface of the bit line is located at a level lower than a bottom surface of the first word line and a bottom surface of the second word line.

14. The semiconductor device of claim 13, wherein the topmost surface of the bit line is located at a level lower than a topmost surface of the substrate.

15. The semiconductor device of claim 13, wherein the bit line is connected to each of the first and second channel patterns.

16. The semiconductor device of claim 13, further comprising a bit line node contact disposed on the bit line, the bit line node contact extending along the first direction.

17. The semiconductor device of claim 13, further comprising an air gap between the insulating substrate and a side surface of the bit line.

18. The semiconductor device of claim 17, further comprising a sacrificial pattern disposed between the insulating substrate and a bottom surface of the bit line, the sacrificial pattern covering a lower portion of the air gap.

19. A semiconductor device, comprising:
a substrate including a lower substrate, an upper substrate, and an insulating substrate disposed between the lower substrate and the upper substrate;
a semiconductor layer on the substrate;
active patterns on the semiconductor layer, each of the active patterns comprising a first channel pattern and a second channel pattern;
bit lines disposed in the insulating substrate, the bit lines extending along a first direction, and spaced apart from each other in a second direction;
buried node contacts penetrating the semiconductor layer in a direction perpendicular to a bottom surface of the substrate; and
word lines penetrating the active patterns in the second direction, the word lines are spaced apart from each other in the first direction,
wherein the first and second directions are parallel to the bottom surface of the substrate and cross each other,
each of the active patterns is connected to a corresponding one of the bit lines through a corresponding one of the buried node contacts, and
the first and second channel patterns of each of the active patterns are spaced apart from each other with the corresponding one of the buried node contacts interposed therebetween.

20. The semiconductor device of claim 19, further comprising data storage patterns respectively connected to the first and second channel patterns of each of the active patterns.
